(19) United States
(12) Patent Application Publication
(10) Pub. No.: US 2022/0199414 A1
(43) Pub. Date: Jun. 23, 2022

(54) APPARATUS FOR POST EXPOSURE BAKE OF PHOTORESIST

(71) Applicant: Applied Materials, Inc., Santa Clara, CA (US)

(72) Inventors: Douglas A. BUCHBERGER, JR., Livermore, CA (US); Dmitry LUBOMIRSKY, Cupertino, CA (US); John O. DUKOVIC, Palo Alto, CA (US); Srinivas D. NEMANI, Sunnyvale, CA (US)

(21) Appl. No.: 17/126,797

(22) Filed: Dec. 18, 2020

(51) Int. Cl. H01L 21/308; H01L 21/67; G03F 7/20

(52) U.S. Cl. CPC H01L 21/3086; G03F 7/2016; H01L 21/67098

(57) ABSTRACT

A method and apparatus for applying an electric field and/or a magnetic field to a photoresist layer without air gap intervention during photolithography processes is provided herein. The method and apparatus include a chamber body, which is configured to be filled with a process fluid, and a substrate carrier. The substrate carrier is disposed outside of the process volume while substrates are loaded onto the substrate carrier, but is rotated to a processing position either simultaneously or before entering the process fluid. The substrate carrier is rotated to a process position parallel to an electrode before an electric field is utilized to perform a post-exposure bake process on the substrate.

### BACKGROUND

### Field

The present disclosure generally relates to methods and apparatus for processing a substrate, and more specifically to methods and apparatus for improving photolithography processes.

### Description of the Related Art

Integrated circuits have evolved into complex devices that can include millions of components (e.g., transistors, capacitors and resistors) on a single chip. Photolithography is a process that may be used to form components on a chip. Generally the process of photolithography involves a few basic stages. Initially, a photoresist layer is formed on a substrate. A chemically amplified photoresist may include a resist resin and a photoacid generator. The photoacid generator, upon exposure to electromagnetic radiation in the subsequent exposure stage, alters the solubility of the photoresist in the development process. The electromagnetic radiation may have any suitable wavelength, for example, a 193 nm ArF laser, an electron beam, an ion beam, or other suitable source.

In an exposure stage, a photomask or reticle may be used to selectively expose certain regions of the substrate to electromagnetic radiation. Other exposure methods may be maskless exposure methods. Exposure to light may decompose the photo acid generator, which generates acid and results in a latent acid image in the resist resin. After exposure, the substrate may be heated in a post-exposure bake process. During the post-exposure bake process, the acid generated by the photoacid generator reacts with the resist resin, changing the solubility of the resist during the subsequent development process.

After the post-exposure bake, the substrate, particularly the photoresist layer, is developed and rinsed. Depending on the type of photoresist used, regions of the substrate that were exposed to electromagnetic radiation are either resistant to removal or more prone to removal. After development and rinsing, the pattern of the mask is transferred to the substrate using a wet or dry etch process.

The evolution of chip design continually requires faster circuitry and greater circuit density. The demands for greater circuit density necessitate a reduction in the dimensions of the integrated circuit components. As the dimensions of the integrated circuit components are reduced, more elements are required to be placed in a given area on a semiconductor integrated circuit. Accordingly, the lithography process must transfer even smaller features onto a substrate, and lithography must do so precisely, accurately, and without damage. In order to precisely and accurately transfer features onto a substrate, high resolution lithography may use a light source that provides radiation at small wavelengths. Small wavelengths help to reduce the minimum printable size on a substrate or wafer. However, small wavelength lithography suffers from problems, such as low throughput, increased line edge roughness, and/or decreased resist sensitivity.

An electrode assembly may be utilized to generate an electric field to a photoresist layer disposed on the substrate prior to or after an exposure process so as to modify chemical properties of a portion of the photoresist layer where the electromagnetic radiation is transmitted for improving lithography exposure/development resolution. However, the challenges in implementing such systems have not yet been adequately overcome.

Therefore, there is a need for improved methods and apparatus for improving immersion field guided post exposure bake processes.

### SUMMARY

The present disclosure generally relates to substrate process apparatus. Specifically, embodiments of the disclosure relate to a substrate apparatus including a chamber body, a substrate carrier, an electrode, a track, and an actuator. The chamber body defining a process volume and includes a bottom surface, one or more sidewalls, and a fluid port disposed through the bottom surface of the chamber body. The electrode is disposed above the bottom surface comprising a major surface. The track is disposed within the chamber body and is configured to guide the substrate carrier to a processing position. A device side of each of the one or more substrates is parallel to a major surface of the electrode while in the processing position. The actuator is operable to position the substrate carrier in a position parallel to at least a portion of the carrier track.

In another embodiment, a substrate processing apparatus includes a chamber body, and a swing assembly. The chamber body defines a process volume and includes a bottom surface, one or more sidewalls, and a fluid port disposed through the bottom surface of the chamber body. The swing assembly includes a substrate carrier with a substrate support surface, an electrode with a major surface disposed parallel to the substrate support surface, and an actuator coupled to the substrate carrier and the electrode and configured to swing the substrate carrier and the electrode about an axis.

In yet another embodiment, a substrate processing method is described. The substrate processing method includes positioning one or more substrates on a substrate carrier while the substrate carrier is in a transfer position. The one or more substrates on the substrate carrier have a substantially horizontal orientation when the substrate carrier is in the transfer position. The method further includes flowing a processing fluid from a fluid port into a process volume of a chamber body and orienting the substrate carrier in a fluid entry position. While in the fluid entry position, the one or more substrates are disposed on the substrate carrier having a fluid entry orientation that is about 60 degrees to about 90 degrees from the substantially horizontal orientation. The method further includes submerging at least a portion of the one or more substrates disposed on the substrate carrier into the processing fluid while in the fluid entry orientation and positioning the substrate carrier at a processing position, wherein the one or more substrates disposed on the substrate carrier are fully submerged within the processing fluid and a device side of the substrate is parallel to a major surface of a second electrode.

In yet another embodiment, a substrate process apparatus includes a base assembly defining a process volume and an electrode assembly. The base assembly includes a bottom surface, one or more sidewalls, a fluid inlet disposed through the chamber body, and a fluid outlet disposed through the chamber body. The electrode assembly includes a perforated electrode and an actuator coupled to a side of the perforated electrode and the base assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIGS. 1A-1E are schematic cross-sectional views of an immersion field guided post exposure bake chamber according to one embodiment described herein.

FIG. 1F is a schematic plan view of the immersion field guided post exposure bake chamber according to the embodiment of FIGS. 1A-1E described herein.

FIGS. 2A and 2B are schematic cross-sectional views of an immersion field guided post exposure bake chamber according to another embodiment described herein.

FIG. 2C is a schematic plan view of the immersion field guided post exposure bake chamber according to the embodiment of FIGS. 2A and 2B described herein.

FIG. 3A is a schematic plan view of a substrate carrier utilized with the immersion field guided post exposure bake chamber of FIGS. 1A-1F according to an embodiment described herein.

FIG. 3B is a schematic bottom view of the substrate carrier utilized with the immersion field guided post exposure bake chamber of FIGS. 1A-1F according to an embodiment described herein.

FIG. 3C is a schematic side view of the substrate carrier utilized with the immersion field guided post exposure bake chamber of FIGS. 1A-1F according to an embodiment described herein.

FIG. 3D a schematic cross-sectional side view of a substrate carrier utilized with the immersion field guided post exposure bake chamber of FIGS. 2A-2C according to an embodiment described herein.

FIG. 3E is another schematic cross-sectional side view of the substrate carrier of FIG. 3D.

FIG. 3F is yet another schematic cross-sectional side view of the substrate carrier utilized with the immersion field guided post exposure bake chamber of FIGS. 2A-2C according to another embodiment described herein.

FIGS. 4A-4D are schematic cross-sectional views of an immersion field guided post exposure bake chamber according to another embodiment described herein.

FIGS. 5A-5C are schematic cross-sectional views of an immersion field guided post exposure bake chamber according to yet another embodiment described herein.

FIG. 6A is a schematic cross-sectional side view of a substrate carrier utilized with the immersion field guided post exposure bake chamber of FIGS. 5A-5C according to an embodiment described herein.

FIG. 6B is a schematic cross-sectional plan view of a portion of the substrate carrier of FIG. 6A according to an embodiment described herein.

FIG. 7A is a schematic cross-sectional view of an immersion field guided post exposure bake chamber according to yet another embodiment described herein.

FIG. 7B is another schematic cross-sectional side view of the immersion field guided post exposure bake chamber of FIG. 7A described herein.

FIG. 7C is a schematic cross-sectional view of an immersion field guided post exposure bake chamber according to yet another embodiment described herein.

FIG. 7D is a plan view of the immersion field guided post exposure bake chambers of FIGS. 7A-7C according to embodiments described herein.

FIG. 8 illustrates operations of a method for performing an immersion post exposure bake process according to an embodiment described herein.

FIG. 9 illustrates operations of a method for performing an immersion post exposure bake process according to another embodiment described herein.

FIG. 10 illustrates operations of a method for performing an immersion post exposure bake process according to yet another embodiment described herein.

FIG. 11 illustrates operations of a method for performing an immersion post exposure bake process according to yet another embodiment described herein.

FIG. 12 illustrates operations of a method for performing an immersion post exposure bake process according to yet another embodiment described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to methods and apparatus for post exposure bake processes. Methods and apparatus disclosed herein assist in reducing line edge/width roughness and improving exposure resolution in a photolithography process for semiconductor application.

The methods and apparatus disclosed herein improve the photoresist sensitivity and productivity of photolithography processes. The random diffusion of charged species generated by a photoacid generator during a post exposure bake procedure contributes to line edge/width roughness and reduced resist sensitivity. An electrode assembly, such as those described herein, is utilized to apply an electric field and/or a magnetic field to the photoresist layer during photolithography processes. The field application controls the diffusion of the charged species generated by the photoacid generator. Furthermore, an intermediate medium is utilized between the photoresist layer and the electrode assembly so as to enhance the electric field generated therebetween.

An air gap defined between the photoresist layer and the electrode assembly results in voltage drop applied to the electrode assembly, thus, adversely lowering the level of the electric field desired to be generated to the photoresist layer. Inaccurate levels of the electric field at the photoresist layer may result in insufficient or inaccurate voltage power to drive or create charged species in the photoresist layer in certain desired directions, thus leading to diminished line edge profile control to the photoresist layer. Thus, an intermediate medium is placed between the photoresist layer and the electrode assembly to prevent an air gap from being created therebetween so as to maintain the level of the electric field interacting with the photoresist layer at a certain desired level. By doing so, the charged species generated by the electric field are guided in a desired direction along the line and spacing direction, substantially preventing the line edge/width roughness that results from inaccurate and random diffusion. Thus, a controlled or desired level of electric field as generated increases the accuracy and sensitivity of the photoresist layer to expose and/or development processes. In one example, the intermediate medium is a non-gas phase medium, such as a slurry, gel, liquid solution, or a solid state medium that may efficiently maintain voltage levels as applied at a determined range when transmitting from the electrode assembly to the photoresist layer disposed on the substrate.

Even while using the intermediate medium, a voltage drop is still present between the photoresist layer and the electrode assembly. This voltage drop is directly related to the distance between the photoresist layer and the electrode assembly. Therefore, reducing the distance between the photoresist layer and the electrode assembly assists in improving the uniformity of the electric field between the photoresist layer and the electrode assembly. Another consideration while using the intermediate medium is bubbling between the photoresist layer and the electrode assembly. Bubbling and the formation of air pockets between the photoresist layer and the electrode assembly causes non-uniformities within the electric field and therefore increases the number of defects and inaccuracies within the photoresist after the post-exposure bake process. The present apparatus and methods described herein for reducing the distance between the photoresist and the electrode assembly beneficially reduces the number of bubbles or air pockets between the photoresist layer and the electrode assembly.

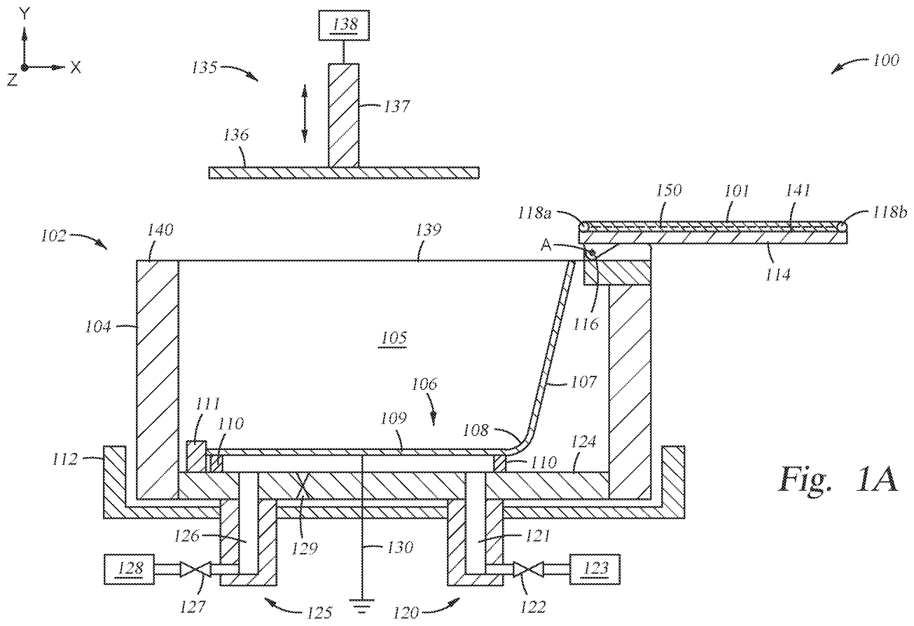

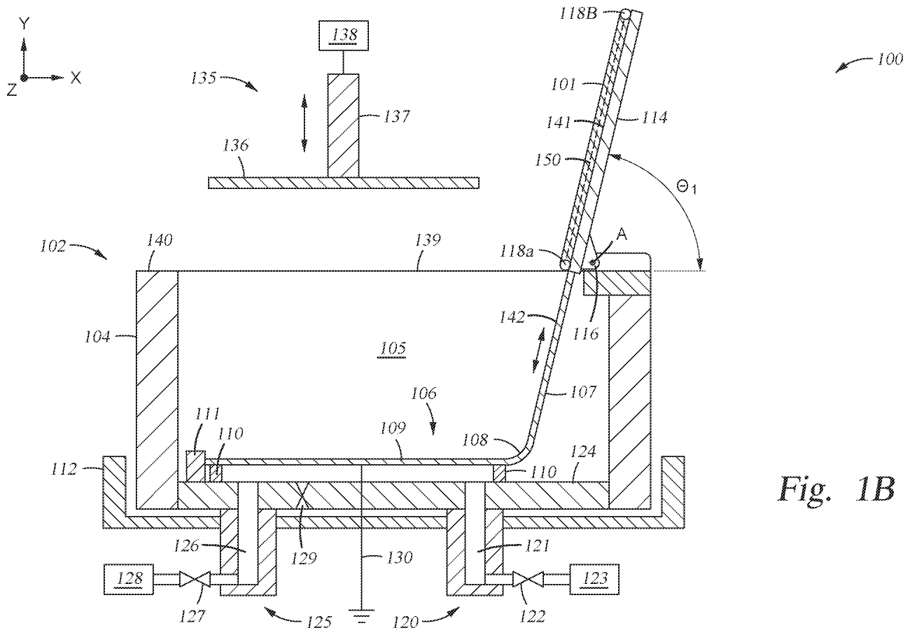

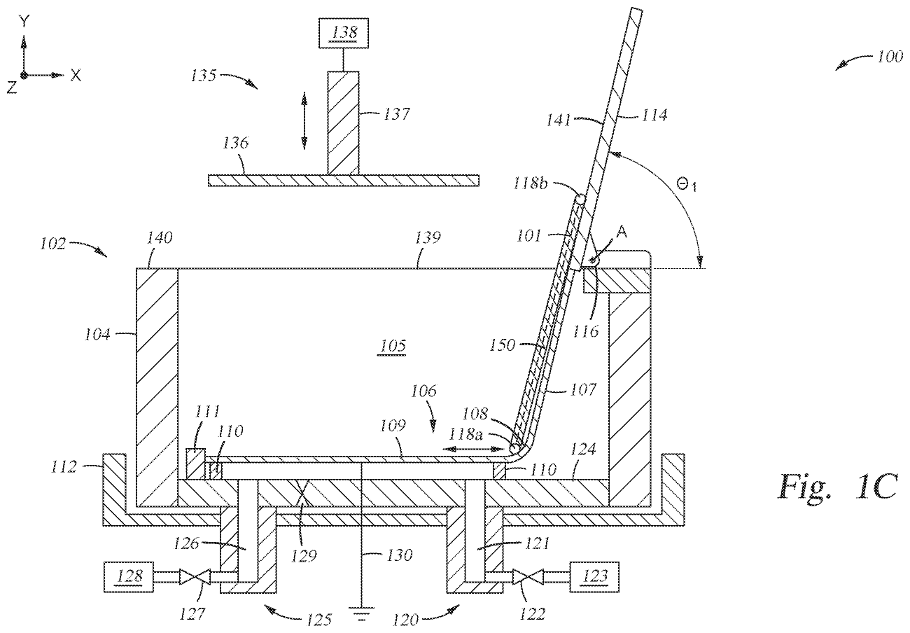

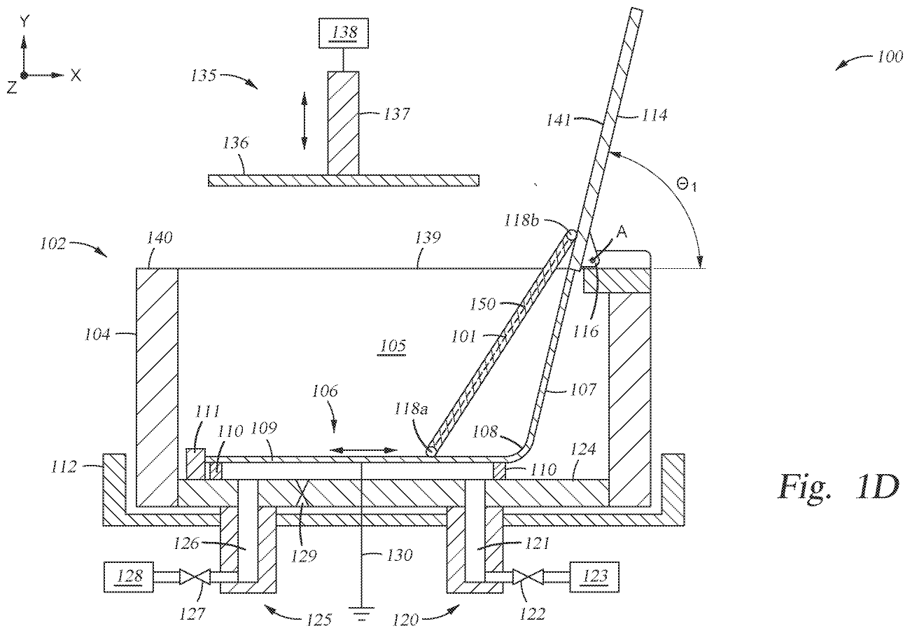

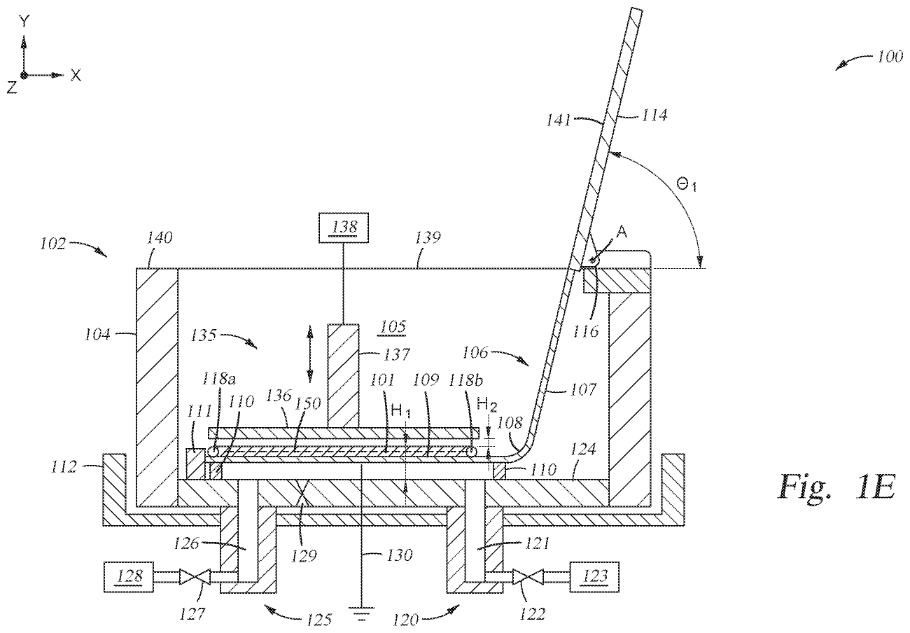

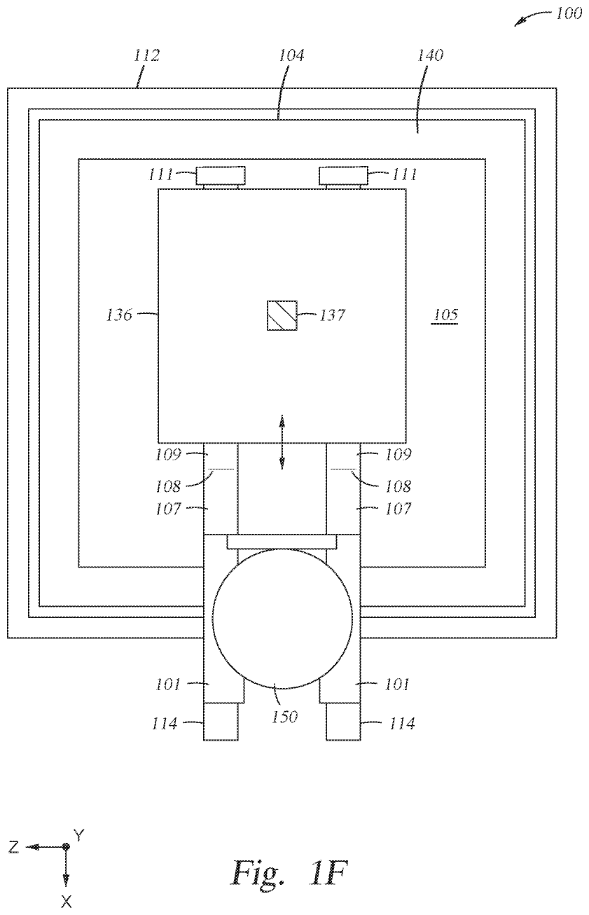

FIGS. 1A-1E are schematic cross-sectional views of an immersion field guided post exposure bake chamber 100 according to one embodiment described herein. The immersion field guided post exposure bake chamber 100 includes a chamber body 102 and an electrode assembly 135. The chamber body 102 is an immersion bath and is configured to receive a substrate 150 on a carrier 101, such that the substrate 150 and the carrier 101 are completely submerged in an intermediate medium 139. The intermediate medium 139 is a non-gas phase medium, such as a slurry, gel, liquid solution, or a solid state medium that may efficiently maintain voltage level as applied at a determined range when transmitting from the electrode assembly 135 to the photoresist layer disposed on the substrate 150.

The chamber body 102 includes a bottom surface 124, one or more sidewalls 104, a first fluid port 120 disposed through the bottom surface 124 of the chamber body 102, a second fluid port 125 disposed through the bottom surface 124 of the chamber body 102, a track 106, and a loading device 114.

The bottom surface 124 and the one or more sidewalls 104 define a process volume 105. The process volume 105 is at least partially filled with the intermediate medium 139 through one or both of the first fluid port 120 and the second fluid port 125 as described herein. The process volume 105 may be at least partially open on one side as the intermediate medium 139 is a liquid, slurry, gel, or solid state medium. The intermediate medium 139 flows from one or both of the first fluid port 120 and the second fluid port 125 to cover the bottom surface 124 of the chamber body 102, before filling the process volume 105 and covering the one or more sidewalls 104. The intermediate medium 139 completely fills the process volume 105, such that the intermediate medium 139 rises to the level of the top surface 140 of the one or more sidewalls 104 and spills over the one or more sidewalls 104 into a fluid accumulation basin 112. The bottom surface 124 and the one or more sidewalls 104 of the chamber body 102 are heated. In some embodiments, the chamber body 102 includes one or more resistive heating elements or heating channels disposed therein (not shown).

The fluid accumulation basin 112 is disposed outside of the chamber body 102, such that the fluid accumulation basin 112 at least partially surrounds the chamber body 102. The fluid accumulation basin 112 is disposed below the bottom surface 124 of the chamber body 102. Alternatively, the fluid accumulation basin 112 may be attached to one or more of the sidewalls 104. The fluid accumulation basin 112 acts as a receptacle or catch basin for the intermediate medium 139 which spills over the sidewalls 104 from the process volume 105. The fluid accumulation basin 112 includes a drain (not shown) to remove the intermediate medium 139 from the fluid accumulation basin 112.

The first fluid port 120 and the second fluid port 125 are disposed through the bottom surface 124 of the chamber body 102. Each of the first fluid port 120 and the second fluid port 125 comprise either a fluid inlet or a fluid outlet. In some embodiments, the first fluid port 120 is a fluid inlet, while the second fluid port 125 is a fluid outlet. In this embodiment, the intermediate medium 139 may be continuously circulated through the process volume 105 as fluid is introduced into the process volume 105 through the first fluid port 120 and fluid is either simultaneously or periodically removed through the second fluid port 120.

In yet other embodiments, only the first fluid port 120 is present and the intermediate medium 139 is removed from the chamber body 102 using an overflow valve 129 between process operations. The overflow valve 129 may be configured to be opened or closed between process operations. In some embodiments, when the overflow valve 129 is in an open position, the intermediate medium 139 drains into the fluid accumulation basin 112. The overflow valve 129 may alternatively be coupled to a conduit (not shown) for removal of the intermediate medium 139. The overflow valve 129 is disposed on the bottom surface 124 of the chamber body 102.

The first fluid port 120 includes a first fluid conduit 121, a first port valve 122, and a first fluid source 123. The first fluid conduit 121 is fluidly connected to the chamber body 102 and the process volume 105. The first fluid conduit 121 is disposed between the bottom surface 124 of the chamber body 102 and the first fluid source 123. The first fluid conduit 121 is a pipe or channel. The first fluid conduit 121 has a first end connected to the process volume 105 on the bottom surface 124 of the chamber body 102 and a second end connected to the first fluid source 123. The first fluid source 123 is a fluid source configured to provide the intermediate medium 139 into the process volume 105. The first fluid source 123 may be a part of a fluid panel for distribution of the intermediate medium 139. The first fluid source 123 may additionally be configured to provide other fluids to the process volume 105, such as cleaning fluids. The first fluid source 123 controls the flow of the intermediate medium 139 into the process volume 105. The first port valve 122 is disposed along the first fluid conduit 121 and between the first fluid source 123 and the process volume 105. The first port valve 122 is a gate valve or throttle valve. The first port valve 122 is configured to control the flow of the intermediate medium 139 into the process volume 105, such that in some embodiments, the first port valve 122 fine tunes the flow of the intermediate medium 139 to the process volume 105. In some embodiments, the first port valve 122 is configured to be in an open or a closed position and can stop fluid from flowing into the process volume 105 from the first fluid source 123. The first fluid source 123 may preheat the process fluid in some embodiments. In some embodiments, the process fluid is preheated to a temperature of about 100° C. to about 200° C., such as about 110° C. to about 150° C., such as about 115° C. to about 130° C.

The second fluid port 125 includes a second fluid conduit 126, a second port valve 127, and a second fluid source 128. The second fluid port 125 may be configured as either an additional fluid inlet or a fluid outlet. When utilized as a fluid inlet, the second fluid conduit 126 is similar to the first fluid conduit 121, the second port valve 127 is similar to the first port valve 122, and the second fluid source 128 is similar to the first fluid source 123. When the second fluid port is configured as a fluid outlet, the second fluid conduit 126 and the second port valve 127 remain the same, but the second fluid source 128 is replaced with a fluid pump. The fluid pump serves to remove fluid from the process volume 105 through the second fluid conduit 126. The first fluid port 120 and the second fluid port 125 are disposed on opposite sides of the bottom wall 124 in order to increase the circulation of the intermediate medium 139 within the process volume 105.

The track 106 is disposed at least partially within the process volume 105. The track 106 includes a first track segment 107, a transition track segment 108, and a second track segment 109. The first track segment 107 is disposed at an angle to a horizontal plane. The horizontal plane may be parallel to the x-axis, the bottom surface 124 of the chamber body 102, or parallel to the second track segment 109. The first track segment 107 is connected to the transition track segment 108 and extends upwards towards the top of the chamber body 102, such that the first track segment 107 extends from the transition track segment 108 towards the top surface 140 of the one or more sidewalls 104. In some embodiments, the first track segment 107 extends along one of the one or more sidewalls 104 and a top portion of the first track segment 107 is level with the top surface of the intermediate medium 139 when the process volume 105 is full. The first track segment 107 is a linear track segment. However, in some embodiment, the first track segment 107 may be curved. The first track segment 107 is angled such that the angle of entry of a substrate and a substrate carrier is a non-zero angle. The angle of entry is the initial angle at which the major plane of the substrate 150 and the substrate carrier 101 intersects the horizontal plane as the substrate 150 and/or the substrate carrier 101 enter the process volume 105 and the intermediate medium 139. The major plane or major surface of the substrate 150 and the substrate carrier 101 is defined as the plane passing through the top surface. With respect to the substrate 150, the major plane or major surface is a plane parallel with the top surface or device side of the substrate 150. With respect to the substrate carrier 101, the major plane or major surface is a plane parallel to the top surface of the substrate carrier 101, where the top surface is parallel to the device side of the substrate 150 when the substrate is disposed therein. The first track segment 107 has an angle of entry of about 70 degrees to about 90 degrees from the horizontal plane. The transition track segment 108 is a curved section of track which connects the first track segment 107 and the second track segment 109. The second track segment 109 is a horizontal track segment. The second track segment 109 is parallel to the horizontal plane and the x-axis. The second track segment 109 is a linear track segment and is disposed on top of connectors 110, which couple the second track segment 109 of the track 106 to the bottom surface 124 of the chamber body 102. The connectors 110 are additionally be grounded, which grounds the track 106. The track 106 is connected to ground by an electrical connection 130. There is an end stop 111 connected to the end of the second track segment 109 opposite the connection to the transition track segment 108. The end stop 111 serves as a guide to ensure the carrier 101 is properly positioned on the second track segment 109 during substrate processing.

The loading device 114 is disposed on top of the top surface 140 of the one or more sidewalls 104. The loading device 114 is configured to couple to the carrier 101 at a top surface 141 of the loading device 114 using one or more connectors. The one or more connectors include a front connector 118a and a back connector 118b. Each of the front connector 118a and the back connector 118b may be actuators for moving the carrier 101 along the loading device 114 and the track 106. In some embodiments, the front connector 118a and the back connector 118b are coupled to the loading device 114 and may transition to being coupled to the track 106 as the carrier 101 moves to a processing position. The front connector 118a and the back connector 118b may be shuttle connections or sliders, such that each of the front connector 118a and the back connector 118b interlock with the loading device 114 and the track 106 during transfer. In some embodiments, the carrier 101 is transferred along the track 106 and the loading device 114 using the front connector 118a and/or the back connector 118b as an actuator. In yet other embodiments, the carrier 101 is acted upon by an outside actuation device or is on a conveyor disposed within the track 106 and the loading device.

The loading device 114 is coupled to the chamber body 102 using an actuator 116. The actuator 116 is coupled to a distal end of the loading device 114 closest to the track 106 and to the top surface 140 of the one or more sidewalls 104. The actuator 116 is configured to swing the loading device 114 along with the carrier 101 from a horizontal position to an angled position. As shown in FIG. 1A, the loading device 114 and the carrier 101 are shown in a horizontal position.

The electrode assembly 135 is disposed above the chamber body 102. The electrode assembly 135 includes an electrostatic mesh 136, a linear actuator 137, and a power source 138. The electrostatic mesh 136 is a conductive mesh which forms an electrode. The electrostatic mesh 136 has a linear bottom surface, which may be defined as a major surface of the electrostatic mesh 136. The major surface of the electrostatic mesh 136 is the surface configured to be parallel to the device side of the substrate 150 when in a processing position. The electrostatic mesh 136 may be woven in one or more layers and includes a plurality of openings disposed therethrough. In some embodiments, the electrostatic mesh 136 is a finely perforated electrode plate. The electrostatic mesh 136 is utilized in order to reduce the amount of bubbles or gas pockets which are trapped under the electrode assembly 135 as the electrode assembly 135 is submerged into the intermediate medium 139. The electrostatic mesh 136 in some embodiments, is a non-metal mesh, such as a silicon carbide mesh. In other embodiments, the electrostatic mesh 136 is a conductive metal mesh, such as a copper, aluminum, or a steel mesh. The linear actuator 137 is coupled to the top surface of the electrostatic mesh 136 in order to enable the vertical movement of the electrostatic mesh 136. The linear actuator 137 may be coupled to the top surface of a process environment (not shown) and extends vertically downward. The power source 138 is electrically coupled to the electrostatic mesh 136 through the linear actuator 137. The power source 138 is configured to apply power to the electrostatic mesh 136. In some embodiments, an electrical potential of up to 5000 V is applied to the electrostatic mesh 136 by the power source 138, such as less than 4000 V, such as less than 3000 V. As shown in FIG. 1A, the electrostatic mesh 136 is disposed in an upper position. In some embodiments, the upper position of the electrostatic mesh 136 is within the process volume 105 of the chamber body 102. In some embodiments, the electrostatic mesh 136 and the electrode assembly 135 are rotated about a vertical axis during post exposure bake processes such that any bubbles accumulated within the electrostatic mesh 136 may be spun out of the mesh and dislodged. The rotation of the electrostatic mesh 136 additionally assists in reducing the effects of defects within the electric field by spreading the effect of the defect over the substrate 150.

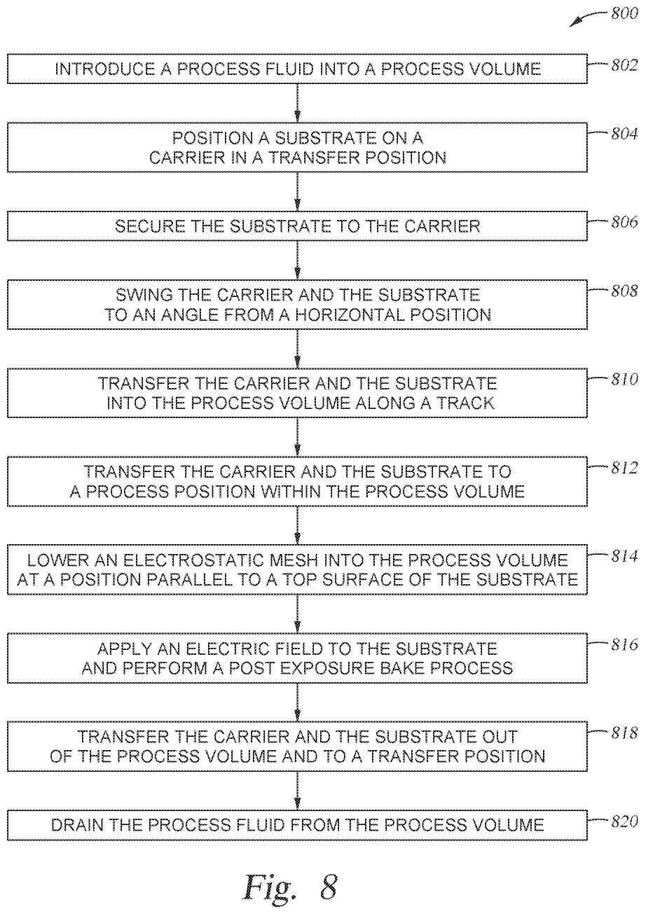

FIGS. 1A-1E illustrate the transfer process of the carrier 101 to a processing position from the initial substrate loading position shown in FIG. 1A. FIGS. 1A-1E illustrate operations discussed in the method 800 of FIG. 8. The method 800 includes a first operation 802, a second operation 804, a third operation 806, a fourth operation 808, a fifth operation 810, a sixth operation 812, a seventh operation 814, an eighth operation 816, a ninth operation 818, and a tenth operation 820. FIG. 1A is shown during or after any of the first, second, or third operations 802, 804, 806.

During the first operation 802, a process fluid, such as the intermediate medium 139, is introduced into the process volume 105. The process fluid is introduced through one or a combination of the first fluid port 120 or the second fluid port 125. The process fluid may be continuously circulated within the process volume 105 and flown over the top surface 140 of the one or more sidewalls 104. In some embodiments, the entire process volume 105 may be emptied of the process fluid between each substrate processed. In yet other embodiments, since the process fluid is continuously circulated, the process volume may remain full between each substrate processed.

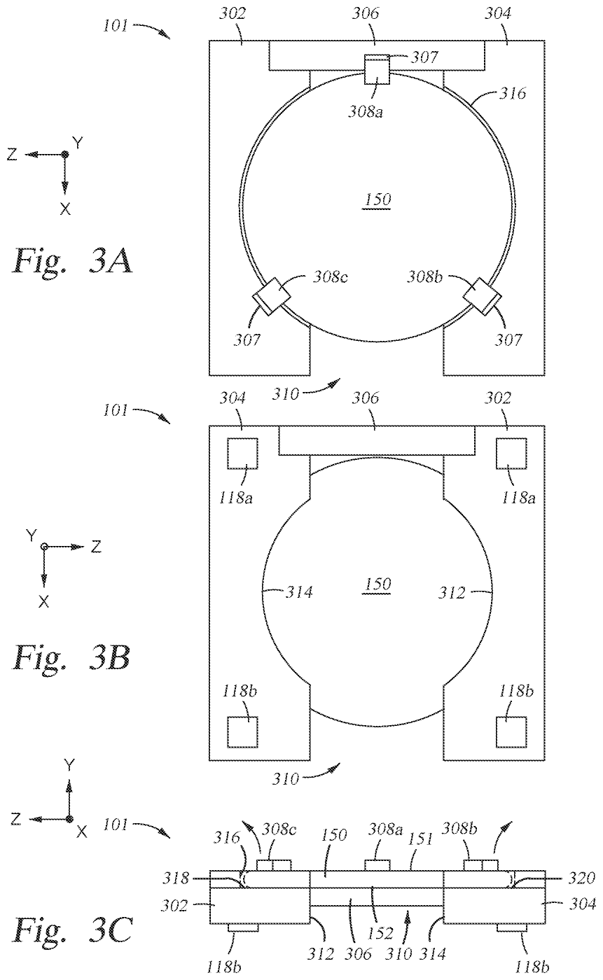

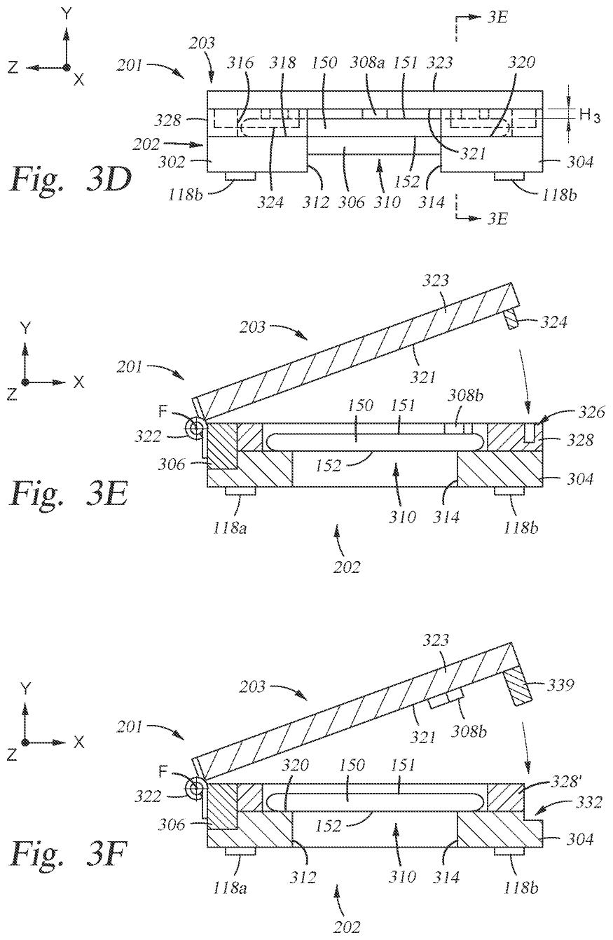

During the second operation 804, a substrate, such as the substrate 150 of FIG. 1F is placed on top of the carrier 101. The carrier 101 may serve as an electrode. The substrate 150 is placed on top of the carrier 101 in a transfer position, such that the substrate 150 is placed on the carrier by a blade of a transfer robot (not shown) from a separate chamber. The transfer position is a position wherein the device side of the substrate 150 is parallel to the horizontal plane. The carrier 101 and the substrate 150 are disposed on top of the loading device 114 while in the transfer position. In the third operation 806, the substrate 150 is secured to the carrier 101. The substrate 150 may be secured to the carrier 101 using mechanical clamps (see FIG. 3C). The substrate 150 may alternatively be secured to the carrier 101 using an extendable shelf built into the carrier 101 or by vacuum chucking.

After the substrate 150 has been secured by the carrier 101 in the transfer position of FIG. 1A, the carrier 101, the substrate 150, and the loading device 114 are swung to an angled position different from the transfer position during a fourth operation 808. The angled position is shown in FIG. 1B. While in the angled position, each of the carrier 101, the substrate 150, and the loading device 114 are swung about an axis A. The orientation of the carrier 101, the substrate 150, and the loading device 114 changed by a first angle θ₁. The first angle θ₁ is about 60 degrees to about 90 degrees, such as about 70 degrees to about 90 degrees, such as about 80 degrees to about 90 degrees, such as about 82 degrees to about 88 degrees. The first angle θ₁ determines the angle at which the substrate 150 and the carrier 101 enter the intermediate medium 139. The first angle θ₁ is taken relative to a horizontal plane, such that the first angle θ₁ may be with respect to the x-axis.

While in the angled position, the loading device 114 is in line with an upper portion of the first track segment 107 of the track 106. The top surface 141 of the loading device 114 is in line with the top surface 142 of the first track segment 107. The alignment of the top surface 141 of the loading device 114 and the top surface 142 of the first track segment 107 enables the carrier 101 to be transferred onto the first track segment 107 from the loading device 114. In some embodiments, the loading device 114 and the first track segment 107 interact while in the angled position and couple together.

After the loading device 114 is swung into the angled position, the carrier 101 and the substrate 150 are transferred from the loading device 114 onto the first track segment 107 and into the process volume 105 during a fifth operation 810. The transfer of the carrier 101 and the substrate 150 from the loading device 114 onto the first track segment 107 is shown in FIG. 1C. During the fifth operation 810, the carrier 101, which holds the substrate 150, is transferred along the track 106. The front connector 118a and the back connector 118b are coupled to one of the track 106 or the loading device 114. As shown in FIG. 1C, the front connector 118a is coupled to the track 106 while the back connector 118b is coupled to the loading device 114 as the carrier 101 is transferred into the process volume 105. The carrier 101 is transferred along the track 106 into the process volume 105 and submerged by the intermediate medium 139. The carrier 101 is submerged by the intermediate medium 139 at an angle as shown in order to reduce the amount of gas pockets or bubbles formed as the carrier 101 and the substrate 150 are submerged.

The carrier 101 reaches the transition track segment 108 before the carrier 101 is fully submerged by the intermediate medium 139. As the carrier 101 reaches the transition track segment 108, the carrier 101 is swung from the angle of the angled position to an angle closer to a horizontal. The swinging motion of the carrier 101 and the substrate 150 as the carrier 101 and the substrate 150 are submerged has been found to further reduce the number and size of bubbles accumulated around the carrier 101 and the substrate 150. The swinging motion additionally is beneficial in that it enables the use of a shallower chamber body 102. The use of a shallow chamber body 102 additionally reduces the size of the overall immersion field guided post-exposure bake chamber 100. The use of separate front connectors 118a and back connectors 118b additionally enables the swinging motion by allowing the carrier 101 to travel along a curved track.

FIG. 1D further illustrates the swinging of the carrier 101 and the substrate 150 as the carrier member 101 is transferred into the process volume 105 and the intermediate medium 139 along the track 106. As the front connector 118a is transferred along the transition track segment 108 and to the second track segment 109, the middle of the carrier 101 may pull away from the track 106 and swing to a more horizontal position.

After the carrier 101 and the substrate 150 are fully submerged within the intermediate medium 139, the carrier 101 and the substrate 150 are transferred to a process position within the process volume 105 during a sixth operation 812. The process position of the carrier 101 and the substrate 150 is shown in FIG. 1E. The process position is a horizontal position, such that the device side of the substrate 150 is parallel to the bottom surface 124 of the chamber body 102. The device side of the substrate 150 disposed within the carrier 101 is a first height H₁ from the bottom surface 124 of the chamber body 102. The first height H₁ may be equal across all of the device side of the substrate 150.

After the carrier 101 and the substrate 150 have been placed in the process position, the electrostatic mesh 136 is lowered into the process volume 105 at a position parallel to the top device side surface of the substrate 150. In some embodiments, the electrostatic mesh 136 may be lowered throughout the first through sixth operations 802-812, but the electrostatic mesh 136 is only brought to a processing position after the carrier 101 has reached the process position. The electrostatic mesh 136 is placed at a position in close contact with and parallel to the device side of the substrate 150, such that the bottom surface of the electrostatic mesh 136 is a second height H₂ from the device side of the substrate 150. The second height H₂ is less than about 7 mm, such as less than about 5 mm, such as less than about 3 mm, such as less than about 1 mm, such as less than about 0.5 mm. In the embodiment described herein, it is possible to reduce the second height H₂ as there are limited mechanical barriers between the device side of the substrate 150 and the electrostatic mesh 136.

Once the seventh operation 814 is complete and the electrostatic mesh 136 is in a process position, an electric field is applied to the substrate 150 and a post exposure bake process is performed during an eighth operation 816. The electric field is distributed between the carrier 101, which serves as a first electrode, and the electrostatic mesh 136, which serves as a second electrode. The electric field may be created by applying a voltage differential of up to about 5000 V, such as up to about 3500 V, such as up to about 3000 V. The electric field between the electrostatic mesh 136 and the substrate 150 is less than about 10×10⁶ V/m, such as less than 1×10⁶ V/m, such as less than 1×10⁵ V/m. The electric field is applied to the substrate 150 until the post exposure bake operation is complete.

After the application of the electric field during the eighth operation 816, the electrostatic mesh 136 is moved away from the process position and transferred out of the process volume 105 during a ninth operation 818. As the electrostatic mesh 136 is removed from the process volume 105, the carrier 101 is also removed from the process volume 105 along a similar path as that which it followed into the process volume 105. During the ninth operation 818, the carrier 101 may be transferred back to the transfer position, such that the substrate 150 may be removed from the carrier by a robot (not shown).

After the carrier and the electrostatic mesh 136 are removed from the process volume 105 during the ninth operation 818, the process volume 105 is optionally drained of process fluid, such as the intermediate medium 139. The process fluid is drained from the process volume 105 during the tenth operation 820.

FIG. 1F is a schematic plan view of the immersion field guided post exposure bake chamber 100 according to one embodiment described herein. The immersion field guided post exposure bake chamber 100 is the same as that described with respect to FIGS. 1A-1E. FIG. 1F illustrates a plan view of the post exposure bake chamber 100 as the carrier 101 is in a loading or transfer position, such as that shown in FIG. 1A. FIG. 1F illustrates positioning of the substrate 150 on the carrier 101 and further illustrates the track 106. The track 106 and the loading device 114 are shown herein as two separate rails, but may be attached by a span between the two portions of the tracks. As shown in FIG. 1F, the electrostatic mesh 136 is sized to completely cover the substrate 150 and the carrier 101 while the carrier is in the process position underneath the electrostatic mesh 136.

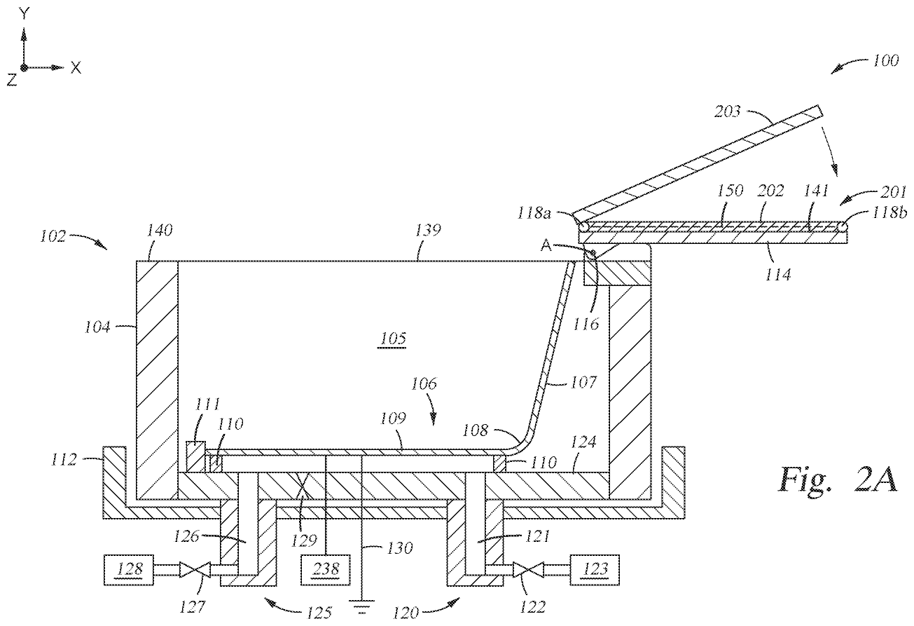

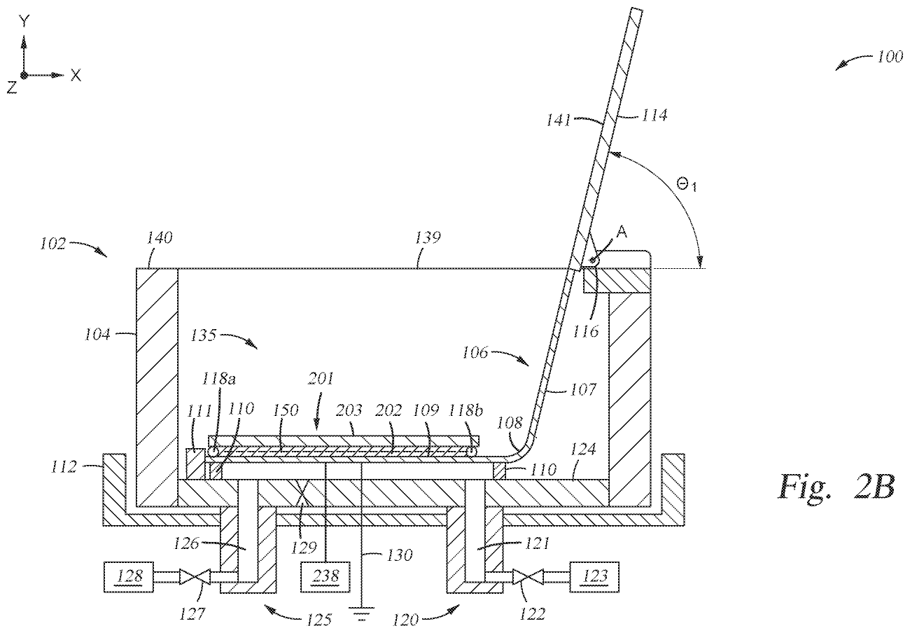

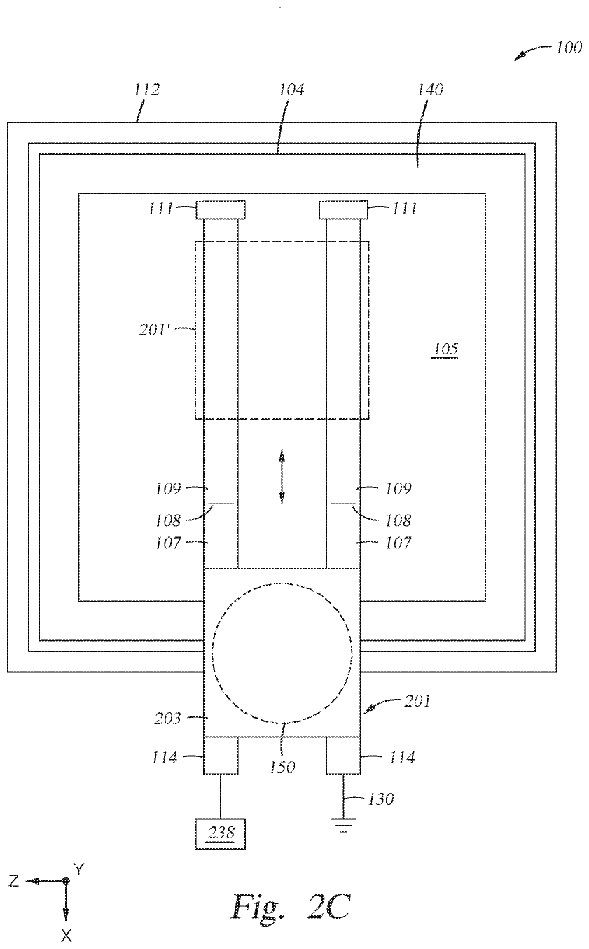

FIGS. 2A and 2B are schematic cross-sectional views of an immersion field guided post exposure bake chamber 100 according to another embodiment described herein. The chamber body 102 of FIGS. 2A-4C is similar to the chamber body 102 of FIGS. 1A-1E. Additionally, the track 106 and the loading device 114 are similar to the track 106 and the loading device 114 of FIGS. 1A-1E. The embodiment of FIGS. 2A-2C is different from the embodiment of FIGS. 1A-1E in that the substrate carrier 101 is replaced with the second substrate carrier 201 and the electrode assembly 135 is replaced by an integrated electrode lid 203 of the substrate carrier 201.

The second substrate carrier 201 includes a lower carrier portion 202 and an electrode lid 203. The electrode lid 203 is coupled to the lower carrier portion 202 at one end, such that the electrode lid 203 swings between a substrate receiving position, such as shown in FIG. 2A, and a substrate processing position, such as shown in FIG. 2B. While in the substrate receiving position, the electrode lid 203 is disposed in an up position. The up position may be an angled position, wherein the electrode lid 203 is disposed at an angle to the carrier portion 202 and a substrate, such as the substrate 150 is able to be loaded onto the carrier portion 202. The attachment and makeup of the electrode lid 203 is described in greater detail with reference to FIGS. 3D-3F. The electrode lid 203 may be an electrostatic mesh, such that there are a plurality of openings disposed through the electrode lid 203. The plurality of openings 203 are beneficial in allowing gas bubbles to escape from between the electrode lid 203 and the substrate 150 as the second substrate carrier 201 is brought to a substrate processing position as shown in FIG. 2B.

The electrode lid 203 swings to a closed position after the substrate 150 is loaded into the carrier portion 202. Closing the carrier portion 202 may assist in securing the substrate 150 to the carrier portion 202 as the second substrate carrier 201 and the substrate 150 are rotated and transferred along the track 106. The electrode lid 203 is electrically coupled to the power source 238 through the track 106. The power source 238 is configured to apply power to the electrode lid 203. In some embodiments, an electrical potential of up to 5000 V is applied to the electrode lid 203 by the power source 238, such as less than 4000 V, such as less than 3000 V. In some embodiments, the carrier portion 202 is electrically grounded 130, such that one of the two rails of the track 106 included a lead line to electrically ground the track 106 while the other of the two rails of the track 106 includes a lead line to couple the power source 238 to the electrode lid 203. The electrode lid 203 may be electrically coupled to the track 106 through one or more of the connectors 118a, 118b.

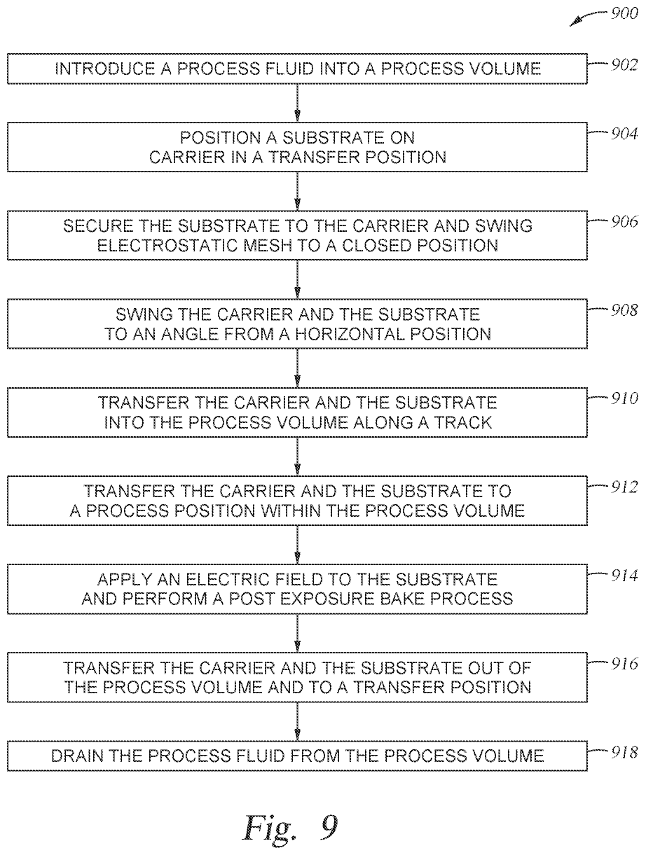

A method 900 can be described with reference to FIGS. 2A, 2B, and 9. The method begins at a first operation 902. During the first operation 902, a process fluid, such as the intermediate medium 139, is introduced into the process volume 105. The first operation 902 is similar to the first operation 802 discussed with respect to FIG. 1A. During a second operation 904, the substrate 150 is placed within the second substrate carrier 201 while the electrode lid 203 is in a loading position. The loading position is one in which the electrode lid 203 is in a raised position.

The second substrate carrier 201 is similarly utilized to secure the substrate 150 during a third operation 906. During the third operation 906, the electrode lid 203 is swung to a closed position and the substrate 150 is secured within the second substrate carrier 201. The substrate 150 is either secured before or during the lowering of the electrode lid 203 to the closed position. Subsequent to the third operation 906, the substrate 150 is transferred into the process volume 105 from the loading device 114 during a fourth operation 908 and a fifth operation 910. The fourth operation 908 and the fifth operation 910 are similar to the fourth operation 808 and the fifth operation 810 of the method 800 of FIG. 8. During the fourth operation 908, the second substrate carrier 201 is swung to an angled position before entering the process volume along the track during the fifth operation 910.

As shown in FIG. 2B, the second substrate carrier 201 is transferred along the track 106 and moved to a process position during a sixth operation 912, similar to the sixth operation 812 of FIG. 8 and the process position of the substrate carrier 101 in FIG. 1E. In the process position, the second substrate carrier 201 is on the second track segment 109.

FIG. 2C is a schematic plan view of the immersion field guided post exposure bake chamber according to the embodiment of FIGS. 2A and 2B described herein. FIG. 2C illustrates the second substrate carrier 201 at a loading position as well as a phantom second substrate carrier 201′ at the process position. The power source 238 is coupled to a first rail of the track 106 while the second rail of the track 106 is grounded 130.

After the second substrate carrier 201 is positioned in the process position, an electric field is applied to the substrate 150. The electric field is applied by providing power to the electrode lid 203 as the substrate 150 is grounded by the carrier portion 202 of the second substrate carrier 201. The application of the electric field to the substrate 150 is similar to the application of the electric field described with respect to the eighth operation 816 of the method 800 of FIG. 8. After the application of the electric field during the eighth operation 816, the second substrate carrier 201 and the substrate 150 are removed from the process fluid and the process volume 105 back to the transfer position. The eighth operation 916 of FIG. 9 is similar to the ninth operation 818 of FIG. 8. The substrate 150 may then be removed by an indexing robot (not shown). Subsequent to (or simultaneously with) the removal of the second substrate carrier 201, the process fluid is drained from the process volume 105 in a ninth operation 918 similar to that described with respect to the tenth operation 810 of FIG. 8.

FIG. 3A is a schematic plan view of a substrate carrier 101 utilized with the immersion field guided post exposure bake chamber 100 of FIGS. 1A-1E according to an embodiment described herein. The substrate carrier 101 includes a first portion 302, a second portion 304, and a span portion 306. The first portion 302 and the second portion 304 are connected by the span portion 306 at a leading edge of the carrier 101. The leading edge of the carrier 101 is the edge of the carrier which is configured to enter the intermediate medium 139 first while moving to the process position. The substrate 150 is placed into a depression 316 formed within both the first portion 302 and the second portion 304. In some embodiments, the depression 316 may also be formed within the span portion 306 if the span portion 306 extends underneath the loading area of the substrate 150. The depression 316 is sized to receive the substrate 150 and prevents the substrate 150 from moving in a lateral direction by enclosing at least a portion of the sides of the substrate 150.

An opening 310 is disposed between the first portion 302 and the second portion 304 and opposite the span portion 306. The opening 310 is disposed to allow for a robot (not shown) to place and remove the substrate 150 from the carrier 101, such that a blade of the robot is temporarily inserted between the first portion 302 and the second portion 304. Once the substrate 150 has been placed on the carrier 101 by the robot, one or more mechanical clamps 308a, 308b, 308c are actuated to a clamping position to secure the substrate 150. The one or more mechanical clamps includes a first clamp 308a, a second clamp 308b, and a third clamp 308c. The first clamp 308a is attached to the span portion 306, the second clamp 308b is attached to the second portion 304, and the third clamp 308c is attached to the first portion 302. Each of the first clamp 308a, the second clamp 308b, and the third clamp 308c are evenly distributed about the depression 316, such that each of the clamps 308a, 308b, 308c is disposed at an angle of about 180 degrees from one another. Each of the first clamp 308a, the second clamp 308b, and the third clamp 308c are disposed within a corresponding one of a plurality of divots 307. Each divot 307 is a small recess formed within the top surface of the carrier 101. The divots 307 are disposed below each of the first clamp 308a, the second clamp 308b, and the third clamp 308c. Each of the divots 307 are disposed slightly further outward from the first clamp 308a, the second clamp 308b, and the third clamp 308c so that the first clamp 308a, the second clamp 308b, and the third clamp 308c may retract from a clamping position into the divots 307 and release the substrate 150. In some embodiments, there may be more or less clamps to secure the substrate 150 inside of the depression 316. In some embodiments there may be only a single clamp, two clamps, or four or more clamps. The number of clamps utilized may depend upon the size of the substrate 150 and the type of clamping mechanism.

FIG. 3B is a schematic bottom view of the substrate carrier 101 utilized with the immersion field guided post exposure bake chamber 100 of FIGS. 1A-1E according to an embodiment described herein. On the bottom of each of the first portion 302 and the bottom portion 304 are the front connector 118a and the back connector 118b as described with respect to FIGS. 1A-1E. As shown in FIG. 3B, there are four connectors 118a, 118b disposed on the bottom surface of the substrate carrier 101. The four connectors 118a, 118b allow for the carrier 101 to be moved along the curved track 106 (See FIGS. 1A-1E). It is contemplated that either the front connectors 118a and/or the back connectors 118b include a motor or actuator assembly to enable movement of the carrier 101 along the track 106. In some embodiments, only the front connectors 118a include a motor or actuator assembly. In other embodiments, only the back connectors 118b include a motor or actuator assembly. In other embodiments, each of the front connectors 118a and the back connectors 118b include a motor or actuator assembly. Although not illustrated herein, it is additionally contemplated that none of the front connectors 118a or the back connectors 118b include a motor assembly and the carrier is instead disposed along a conveyor system and is coupled to the conveyor by any of the front connectors 118a or the back connectors 118b.

The substrate 150 is disposed within the depression 316. The depression. As shown in FIG. 3B, the depression extends inwards from the edge outer of the substrate 150 so as to form a shelf on which the substrate 150 rests. The inner surfaces of the shelf are disposed below the bottom of the substrate and are shown as a first inner surface 312 and a second inner surface 314. The first inner surface 312 and the second inner surface 314 are concave surfaces. The first inner surface 312 is disposed along the inside edge of the first portion 302 and the second inner surface 314 is disposed along the inside edge of the second portion 304. The first inner surface 312 and the second inner surface 314 form the opening 310 along the bottom of the carrier 101. Although shown as comprising as having the opening 310 formed below the majority of the substrate 150, it is contemplated that the opening 310 may be narrower and over a smaller area radial portion of the substrate 150 as to provide a larger shelf for the substrate 150 and to increase the surface area contact of the carrier 101 with the substrate 150. However, by reducing the size of the shelf formed by the depression 316, less air pockets are formed around the substrate 150 during immersion within the intermediate medium 139.

FIG. 3C is a schematic side view of the substrate carrier 101 utilized with the immersion field guided post exposure bake chamber 100 of FIGS. 1A-1E according to an embodiment described herein. FIG. 3C illustrates a first shelf 318 and a second shelf 320 formed on the substrate carrier 101. The first shelf 318 is disposed on the first portion 302 while the second shelf 320 is formed on the second portion 304. The bottom surface 152 of the substrate 150 contacts the surface of the first shelf 318 and the second shelf 320. The device side 151 of the substrate 150 is disposed opposite the first shelf 318 and the second shelf 320 and is clamped by the first clamp 308a, the second clamp 308b, and the third clamp 308c. The clamps 308a, 308b, 308c are able to be actuated between an opened and a closed position. As shown in FIG. 3C, the clamps 308a, 308b, 308c are in a closed position. To move to an open position, the clamps 308a, 308b, 308c may be actuated about an axis to rotate to an upward position. Alternatively, the clamps 308a, 308b, and 308c may move laterally so that the clamps 308a, 308b, 308c extend radially outward to move to the opened position and radially inward to the closed position.

FIG. 3D is a schematic cross-sectional side view of a substrate carrier 201 utilized with the immersion field guided post exposure bake chamber of FIGS. 2A-2C according to an embodiment described herein. The substrate carrier 201 is sometimes referred to herein as a second substrate carrier 201 to differentiate from the first substrate carrier 101 of FIGS. 3A-3C. The substrate carrier 201 of FIGS. 3D-3E includes a lower carrier portion 202 and an electrode lid 203. The lower carrier portion 202 is similar in structure to the substrate carrier 101 of FIGS. 3A-3C.

The lower carrier portion 202 includes the first portion 302, the second portion 304, and the span portion 306. The depression 316 is formed within both the first portion 302 and the second portion 304. The opening 310 is disposed between the first portion 302 and the second portion 304 and opposite the span portion 306. The one or more mechanical clamps 308a, 308b, 308c are additionally still utilized. The lower carrier portion 202 of FIGS. 3D and 3E further includes a third portion 328, which forms a lip extending upward from each of the first portion 302 and the second portion 304. The lip of the third portion 328 forms a wall around an outer portion of the substrate 150 furthest from the span portion 306. The third portion 328 enables better securing of the substrate 150 to the lower carrier portion 202. The third portion 328 includes a groove 326 formed in the top surface. The groove 326 is sized to receive a protrusion 324 and secure the protrusion 324 (shown in phantom in FIG. 3D) within the groove 326 during transfer of the substrate carrier 201 between the loading position and the processing position.

The electrode lid 203 includes a perforated electrode 323, the protrusion 324, and an actuator 322 (shown in FIG. 3E). As previously described the perforated electrode 323 may be a perforated plate or a mesh. The perforated electrode 323 is formed from an electrically conductive material, such that the perforated electrode 323 may be electrified and form an electric field between the perforated electrode 323 and the substrate 150. The perforated electrode 323 has a plurality of openings (not shown) formed therethrough to allow gas to flow from the volume below the bottom surface 321 of the perforated electrode 323 and within the substrate carrier 201 out of the volume within the substrate carrier 201. The plurality of openings are spaced to allow for the gases to escape, while maintaining structural integrity of the perforated electrode 323. The reduction of gas and bubbles within the volume between the substrate 150 and the perforated electrode 323 improves the uniformity of the electric field between the perforated electrode 323 and the substrate 150. Structural integrity assists in keeping the perforated electrode 323 in a uniform shape and reduces deformation of the perforated electrode 323 as the perforated electrode 323 is actuated between an opened and a closed position.

The perforated electrode 323 is placed at a position in close contact with and parallel to the device side of the substrate 150, such that the bottom surface 321 of the perforated electrode 323 is a third height H₃ from the top surface 151 of the substrate 150. The third height H₃ is less than about 7 mm, such as less than about 5 mm, such as less than about 3 mm, such as less than about 1 mm, such as less than about 0.5 mm. The third height H₃ may be reduced as there are limited mechanical barriers between the device side of the substrate 150 and the perforated electrode 323.

As shown in FIG. 3E, the actuator 322 is coupled to the perforated electrode 323 one end. The actuator 322 is also coupled to the lower carrier portion 202 on one end, such that the perforated electrode 323 and the lower carrier portion 202 are coupled together at the actuator 322. The actuator 322 may be a rotary actuator, such as a stepper motor, a servo motor, an AC brushless motor, a DC brushed motor, a DC brushless motor, or a direct drive motor. The actuator 322 is connected to the perforated electrode 323 on one end as well as the span portion 306. The actuator 322 is configured to swing the perforated electrode 323 about an axis F, such that the perforated electrode 323 swings from an opened to a closed position after a substrate 150 is loaded into the lower carrier portion 202. As the actuator 322 swings the perforated electrode 323 to a closed position, the protrusion 324 is inserted into the groove 326 and secures the opposite end of the perforated electrode 323 to the lower carrier portion 202. The protrusion 324 extends from the bottom surface 321 of the perforated electrode 323. In some embodiments, a protrusion may instead extend from the third portion 328 of the lower carrier portion 202 and a groove is disposed within the perforated electrode 323 to receive the protrusion.

FIG. 3F is yet another schematic cross-sectional side view of the substrate carrier 201 utilized with the immersion field guided post exposure bake chamber 100 of FIGS. 2A-2C according to another embodiment. The substrate carrier 201 of FIG. 3F is similar to the substrate carrier 201 of FIGS. 3D and 3E. The substrate carrier 201 of FIG. 3F is different from the substrate carrier 201 of FIGS. 3D and 3E in that the clamps 308a, 308b, 308c are coupled to the bottom surface 321 of the perforated electrode 323 and the third portion 328 is replaced by a modified third portion 328′. The modified third portion 328′ includes an outer groove 332. The outer groove 332 is formed from the modified third portion 328′ and the second portion 304. The outer groove 332 is sized to receive a protrusion 339. The outer groove 332 is disposed radially outward from the modified third portion 328′ and on the outer edge of the perforated electrode 323. The protrusion 339 is different from the protrusion 324 of FIGS. 3D and 3E in that the protrusion 339 of FIG. 3F additionally may form a wall between the first portion 302 and the second portion 304.

The protrusion 339 surrounds the substrate carrier 201, which improves electric field uniformity near the edges of the substrate 150 during processing. In some embodiments, each of the first portion 302, the second portion 304, the span portion 306, and the protrusion 339 are coated with a similar material on at least a portion of the surfaces of the first portion 302, the second portion 304, the span portion 306, and the protrusion 339 in order to better facilitate formation of a uniform magnetic field between the top surface 151 of the substrate 150 and the perforated electrode 323.

Each of the clamps 308a, 308b, 308c being coupled to the bottom surface 321 of the perforated electrode 323 further reduces the mechanical complexity of clamping the substrate 150 because the substrate 150 is clamped into place within the substrate carrier 201 as the perforated electrode 323 swings to a closed position. Although not explicitly shown in the figures, the clamps 308a, 308b, 308c may alternatively be coupled to the bottom surface 321 of the perforated electrode 323 in the embodiments of FIGS. 3D and 3E.

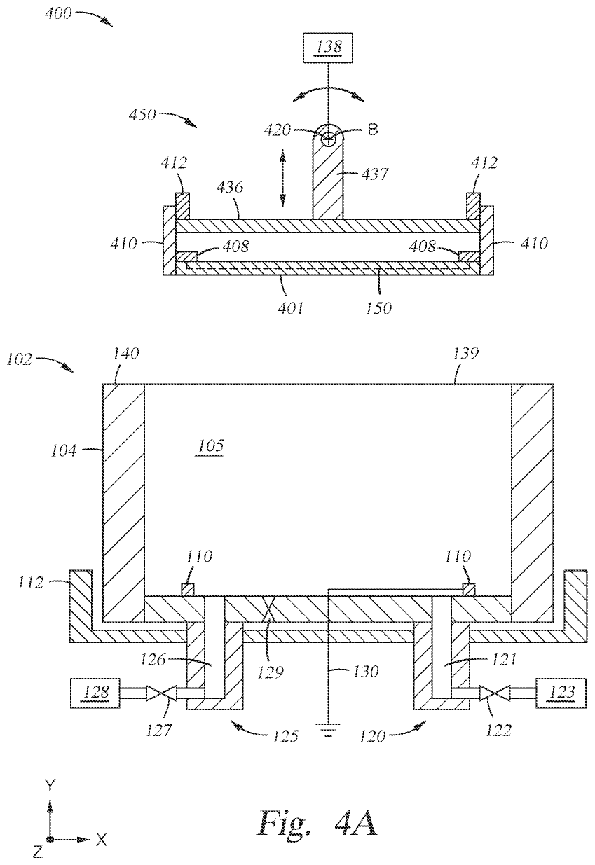

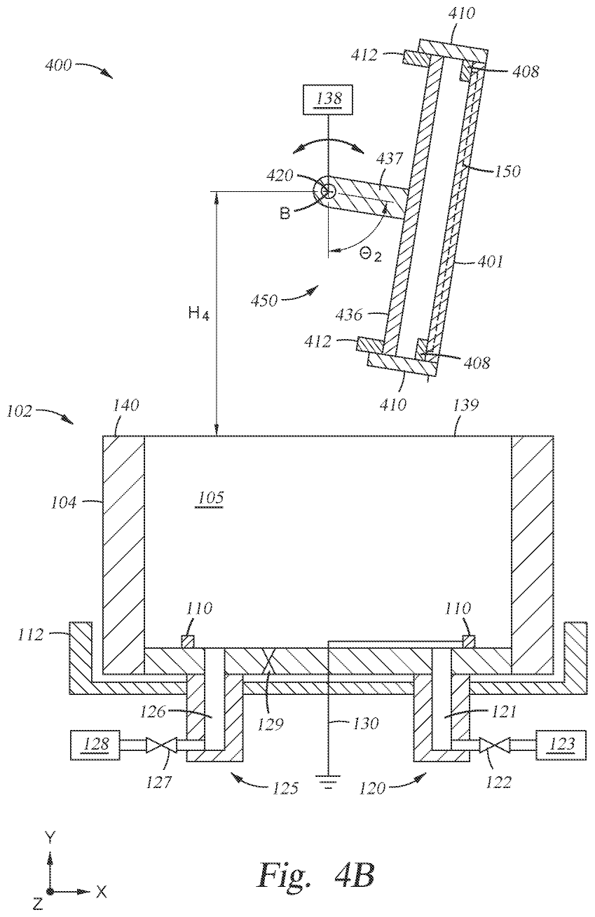

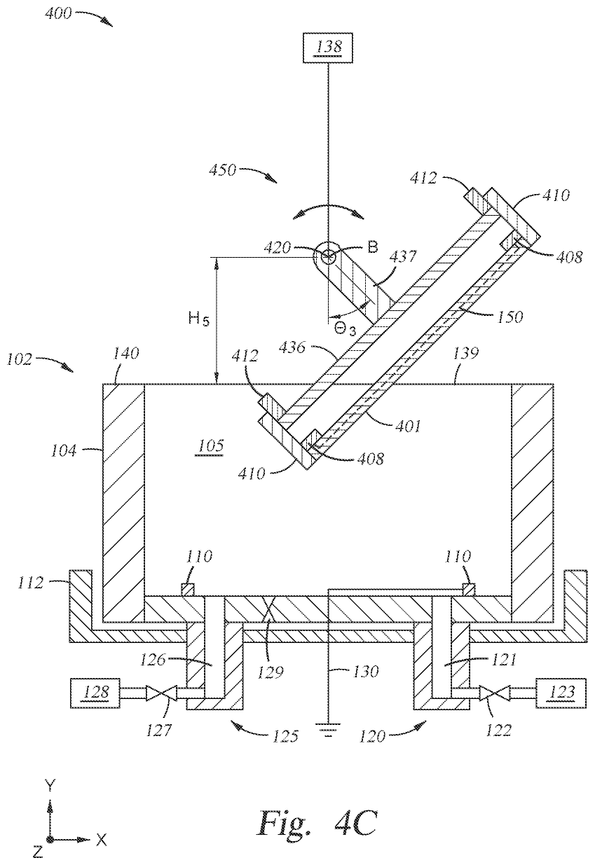

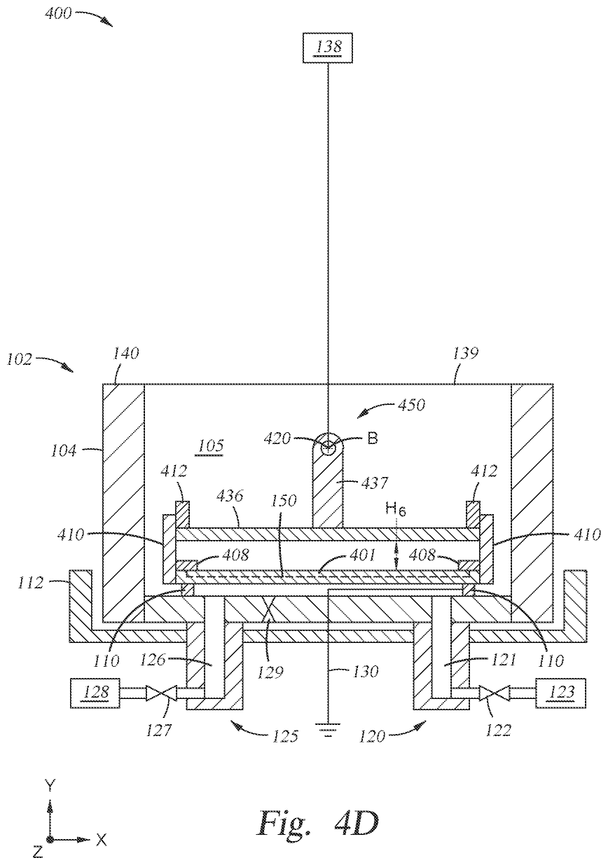

FIGS. 4A-4D are schematic cross-sectional views of an immersion field guided post exposure bake chamber 400 according to another embodiment described herein. The chamber body 102 of FIGS. 4A-4D is similar to the chamber body 102 of FIGS. 1A-1E. The chamber body 102 of the embodiment of FIG. 4A-4D does not utilize the track 106, the loading device 114, or the actuator 116. The substrate 150 is instead transferred into the process volume 105 and the intermediate medium 139 using a swing assembly 450. The swing assembly 450 is configured to hold the substrate 150 and includes an electrode 436. The swing assembly 450 is configured to receive the substrate 150 in a horizontal position and swing the substrate 150 and the electrode 436 into the process volume 105.

As illustrated in FIG. 4A, the swing assembly 450 includes the electrode 436, an actuator coupling 437, a swing carrier 401, and a power source 138. The electrode 436 is a solid plate electrode or an electrostatic mesh as described herein. The electrode 436 is disposed, such that a bottom surface of the electrode 436 is parallel to the top surface of the substrate 150 and the swing carrier 401. In some embodiments, the bottom surface of the electrode 436 may be defined as a major surface of the electrode 436, such that the major surface of the electrode 436 is the closest parallel surface to the device side of the substrate 150 once the substrate 150 is disposed within the swing carrier 401. The electrode 436 is electrically coupled to the power source 138 through the actuator coupling 437. The swing carrier 401 is electrically isolated from the electrode 436 and simultaneously coupled to the electrode 436 by one or more linking members 410. The swing carrier 401 is similar to the carrier 101 of FIG. 3, but the swing carrier 401 is coupled to the one or more linking members 410.

The one or more linking members 410 are rigid electrical insulators. The one or more linking members 410 may be formed from any one of a ceramic, a polymer, or a combination of ceramic and a polymer. In some embodiments, the one or more linking members 410 are made of quartz or alumina. The one or more linking members 410 are coupled to the edges of the electrode 436 and the swing carrier 401. The one or more linking members 410 are rigid to maintain a constant displacement between the electrode 436 and the swing carrier 401.

In some embodiments, the one or more linking members 410 may be coupled with one or more linear actuators 412, which enable the displacement between the electrode 436 and the swing carrier 401 to be increased or decreased. The one or more linear actuators 412 are connected to the electrode 436 and the one or more linking members 410 and move the one or more linking members 410 with respect to the electrode 436. The one or more linking members 410 is fixed to the swing carrier 401 and enable the movement of the swing carrier 401 closer to and further away from the electrode 436 as the one or more linear actuators 412 actuate the one or more linking members 410.

It is envisioned the one or more linear actuators 412 would space apart the electrode 436 and the swing carrier 401 during loading of the substrate 150 into the swing carrier 401. The space between the electrode 436 and the swing carrier 401 would then be reduced by the one or more linear actuators 412 after the substrate 150 has been loaded onto the swing carrier 401 and the swing carrier 401 is prepared for processing. Reducing the displacement between the electrode 436 and the swing carrier 401 assists in maintaining a uniform electric field between the electrode 436 and the substrate 150 during post exposure bake processes.

The substrate 150 is secured to the swing carrier 401 using one or more clamps 408. The one or more clamps 408 are similar to the clamps 308a, 308b, 308c described with respect to FIGS. 3A-3B. In some embodiments, the one or more clamps 408 are a pneumatic or a hydraulic clamp, such that a ring surrounding the substrate is inflated or filled to apply pressure to an edge portion or the top surface of the substrate 150.

The actuator coupling 437 couples to electrode 436 to an actuator 420. The actuator 420 is configured to rotate the entire swing assembly about a swing axis B. The swing axis B is offset from both the electrode 436 and the swing carrier 401.

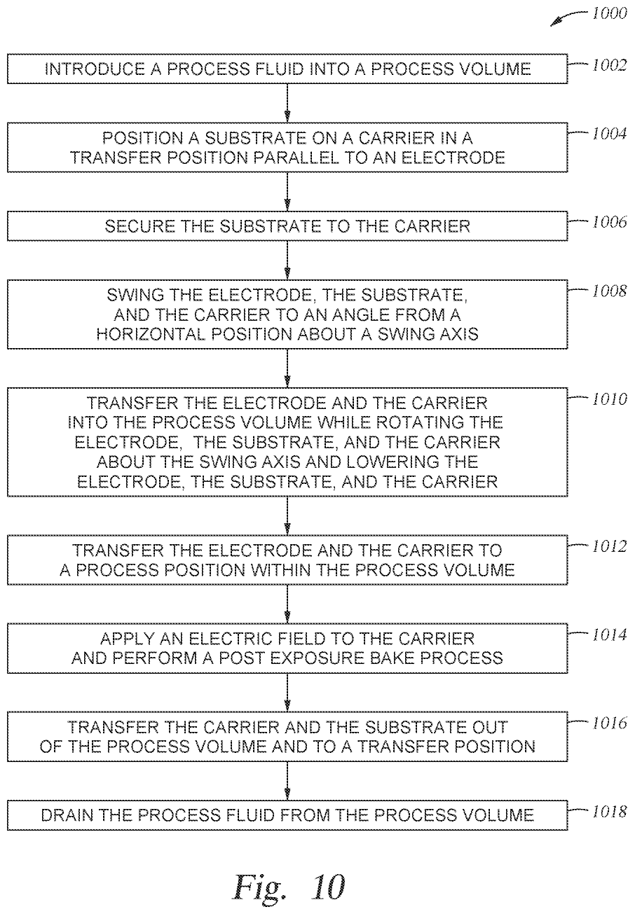

FIGS. 4A-4D illustrate operations of the method 1000 of FIG. 10. The method 1000 includes a first operation 1002, a second operation 1004, a third operation 1006, a fourth operation 1008, a fifth operation 1010, a sixth operation 1012, a seventh operation 1014, an eighth operation 1016, and a ninth operation 1018. The operations are performed with respect to the apparatus of FIGS. 4A-4D as described herein.

The first operation 1002, the second operation 1004, and the third operation 1006 are illustrated with respect to FIG. 4A. During the first operation 1002, the process volume 105 is filled with a process fluid, such as the intermediate medium 139. The process fluid is introduced through one of the first fluid port 120 or the second fluid port 125. The first operation 1002 is similar to the first operation 802 described with respect to FIG. 8 and FIGS. 1A-1E.

The second operation 1004 includes positioning the substrate 150 on the swing carrier 401, while the swing carrier 401 is in a transfer position. The transfer position is a position parallel to electrode 436 and the horizontal plane as previously described. The substrate 150 is placed onto the swing carrier 401 using a robot (not shown). The swing carrier 401 and the electrode 436 are in a spaced position while positioning the substrate 150 onto the swing carrier 401.

After the substrate 150 is placed on the swing carrier 401, the substrate 150 is secured to the swing carrier 401 during the third operation 1006. The substrate 150 is secured to the swing carrier 401 using one or more clamps 408. The one or more clamps 408 are either mechanical, pneumatic, or hydraulic clamps. The securing of the substrate 150 to the swing carrier 401 enables to the swing carrier 401 and the electrode 436 to be rotated about the swing axis B without the substrate 150 moving or falling out of the swing carrier 401.

After the substrate 150 is secured to the swing carrier 401, the electrode 436, the swing carrier 401, and the substrate 150 are swung to an angled position from the horizontal transfer position during a fourth operation 1008. The swing carrier 401, the electrode 436, and the substrate 150 are swung about the swing axis B to an angled position as illustrated in FIG. 4B. The swing assembly 450 is disposed above the chamber body 102 as the swing assembly 450 rotates about the swing axis B. The swing axis B may be disposed at a height H₄ of over half of the substrate 150 from the top surface of the intermediate medium 139. In some embodiments, the height H₄ is about 100 mm to about 300 mm, such as about 150 mm to about 250 mm. The swing angle θ₂ of the swing assembly 450 from a vertical or transfer position is about 60 degrees to about 90 degrees, such as about 70 degrees to about 90 degrees, such as about 80 degrees to about 90 degrees, such as about 82 degrees to about 88 degrees. The swing angle θ₂ is the angle of entry of the substrate 150 and the carrier 401 with respect the horizontal plane. The angle of entry of the substrate 150 and the carrier 401 is also shown as being taken with respect to a top horizontal surface of the intermediate medium 139 when the process volume 105 is filled with the intermediate medium 139. It has been found that an angle of entry of over 80 degrees substantially reduces the quantity of bubbles and air pockets formed around the substrate 150, the swing carrier 401, and the electrode 436.

During the fifth operation 1010, the electrode 436, the swing carrier 401, and the substrate 150 are transferred into the process volume and submerged in the intermediate medium 139. The fifth operation 1010 is illustrated in FIG. 4C. As the electrode 436, the swing carrier 401, and the substrate 150 are submerged in the intermediate medium 139, the swing assembly 450 is rotated from the angled position of the fourth operation 1008 to a more horizontal position. Swinging the swing assembly 450 about the swing axis B simultaneously while lowering the entire swing assembly 450 causes the electrode 436, the swing carrier 401, and the substrate 150 to be submerged along a curved path. Swinging the swing assembly 450 as the swing assembly 450 is submerged in the intermediate medium 139 has been shown to reduce the accumulation of bubbles about the electrode 436, the swing carrier 401, and the substrate 150. In some embodiments, the swing assembly 450 may be completely or nearly completely submerge in the intermediate medium 139 before the swing assembly 450 is rotated about the swing axis B to a horizontal position. The swing axis B may be a height H₅ of about −150 mm to about 150 mm above the top surface of the intermediate medium 139, such about −100 mm to about 100 mm, such as about −50 mm to about 50 mm before the swing assembly 450 begins rotating back to the horizontal position from the angled position of FIG. 4B. The swing angle 83 of entry as the last portion of the swing assembly 450 is submerged into the intermediate medium 139 is about 5 degrees to about 60 degrees, such as about 10 degrees to about 45 degrees.

After the entire electrode 436, the swing carrier 401, and the substrate 150 have been submerged in the intermediate medium 139, the swing assembly 450 is transferred to a process position within the process volume in a sixth operation 1012. The process position of the swing assembly 450 is illustrated in FIG. 4D. In FIG. 4D, the device side of the substrate 150 is positioned horizontally, which in the example of FIG. 1 is also parallel to the bottom surface 124 of the chamber body 102. The swing carrier 401 is rested on top of one or more connectors 110. The one or more connectors 110 electrically and mechanically couple the swing carrier 401 to the bottom surface 124 of the chamber body 102. The one or more connectors 110 are electrically grounded 130. The grounding of the swing carrier 401 additionally grounds the substrate 150. Alternatively to the substrate and the swing carrier 401 being grounded by the connectors 110, the swing carrier 401 is grounded by a connection which passes through the one or more linking members 410 and which is run through the actuator coupling 437 and to a grounded component (not shown) in a similar manner to the connection of the power source 138 with the electrode 436.

While in the process position, a seventh operation 1014 of applying an electric field to the substrate 150 and performing a post exposure bake process is performed. The seventh operation 1014 is similar to the eighth operation 816 of the method 800 of FIG. 8. The height H₆ between the electrode 436 and the device side of the substrate 150 is less than about 7 mm, such as less than about 5 mm, such as less than about 3 mm, such as less than about 1 mm, such as less than about 0.5 mm. In the embodiment described herein, it is possible to reduce the height H₆ as there are limited mechanical barriers between the device side of the substrate 150 and the electrode 436.

After the post exposure bake process of the seventh operation 1014 is performed, the electrode 436, the swing carrier 401, and the substrate 150 are transferred out of the process volume 105 during an eighth operation 1016. During the eighth operation 1016, the intermediate medium 139 in a method similar to, but reversed from, the method utilized to place the electrode 436, the swing carrier 401, and the substrate 150 within the process volume 105.

During a ninth operation 1018, the process fluid, such as the intermediate medium 139, is drained from the process volume 105 through one of the first fluid source 120, the second fluid source 125, or the overflow valve 129. The draining of the process fluid from the process volume 105 of the ninth operation 1018 is similar to the tenth operation 820 of the method 800 of FIG. 8.

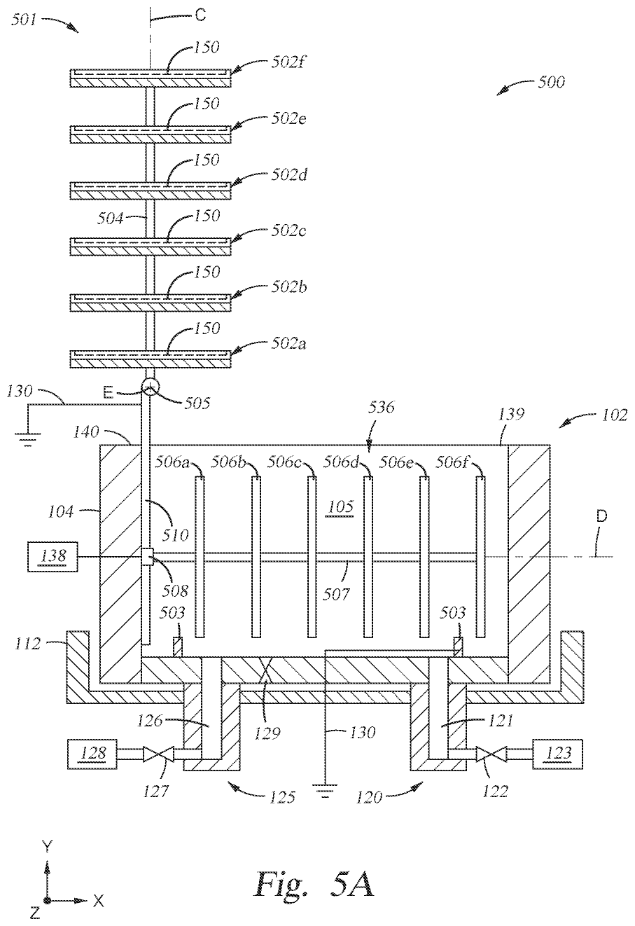

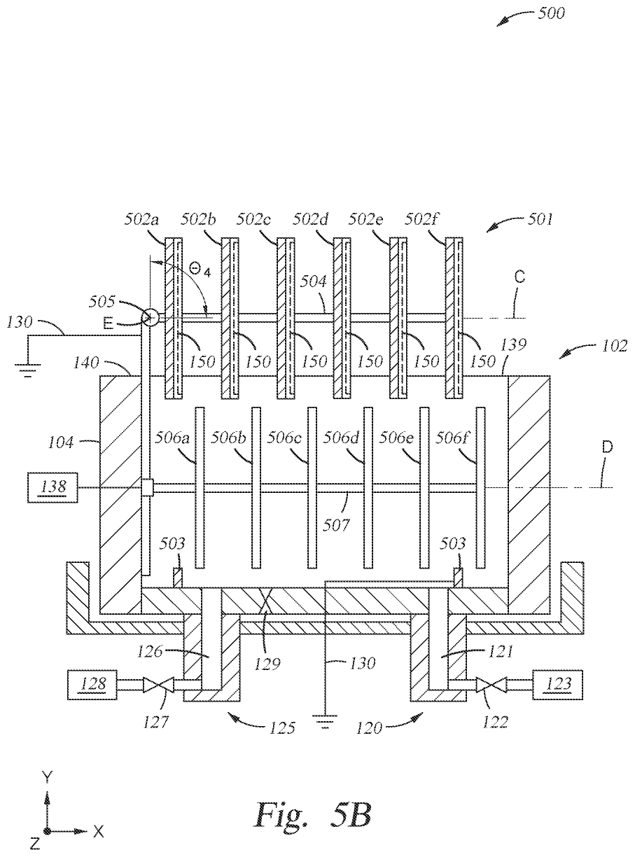

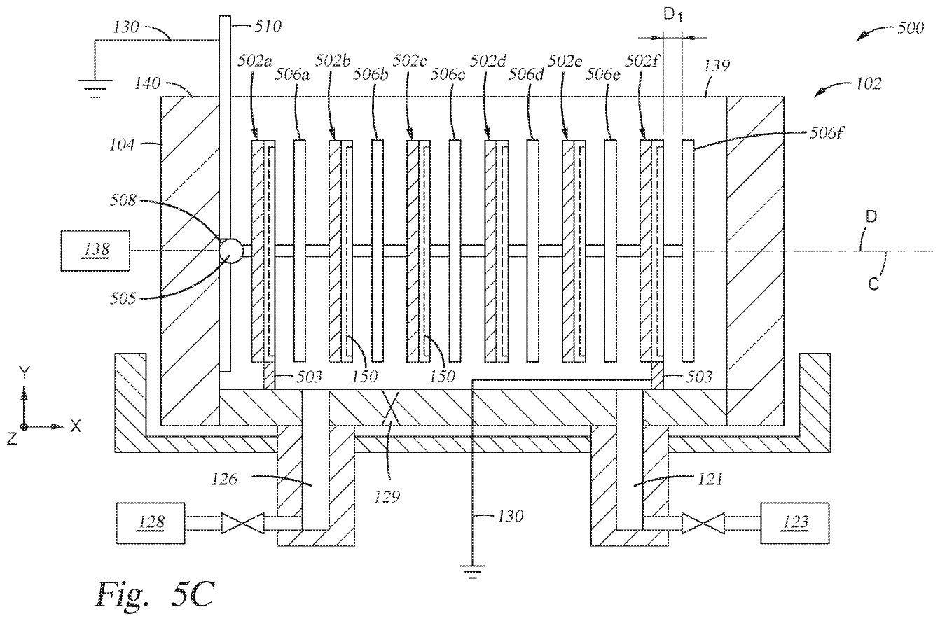

FIGS. 5A-5C are schematic cross-sectional views of an immersion field guided post exposure bake chamber 500 according to yet another embodiment described herein. The immersion field guided post exposure bake chamber 500 includes a chamber body 102 and a substrate batch carrier 501. The batch carrier 501 is configured to hold a plurality of substrates. The plurality of substrates may be placed on the batch carrier 501 using one or more robots (not shown). The chamber body 102 is similar to the chamber body 102 described with respect to FIGS. 1A-1E. The chamber body 102 of FIG. 5A further includes a sidewall track 510 and a batch electrode device 536 attached thereon. The connectors 110 of FIGS. 1A-1E and 4A-4D are additionally replaced with supports 503.

The batch electrode device 536 includes a plurality of single electrodes 506a-506f. The batch electrode device 536 is disposed within the process volume 105 of the chamber body 102 and is configured to be completely submerged in process fluid, such as the intermediate medium 139, while the process volume 105 is sufficiently full of intermediate medium 139. The plurality of single electrodes 506a-506f are disposed parallel with one another and perpendicular to the bottom surface 124 of the chamber body 102. Each of the single electrodes 506a-506f include a major surface, which is configured to be a planar surface parallel to the substrate 150 while the substrate 150 is in a process position. The major surface may be the largest planar surface of the single electrodes 506a-506f and configured to form an electric field. The plurality of electrodes 506a-506f are disposed along one or more support beams 507. The one or more support beams 507 are disposed perpendicular to the electrodes 506a-506f. The one or more support beams 507 are coupled to a sidewall 104 of the chamber body 102 at a coupling 508. The plurality of electrodes 506a-506f are spaced along the one or more support beams 507 and centered about batch electrode axis D. The batch electrode axis D is perpendicular to the chamber body 102 sidewall 104.

The coupling 508 may be disposed on a track (not shown) separate, but parallel to, the sidewall track 510. Alternatively, each of the electrodes 506a-506f may be individually mounted onto a sidewall 104 of the process chamber without the use of the support beam. Mounting each electrode of the plurality of electrodes 506a-506f allows for each electrode to be replaced separately and reduces the mechanical complexity within the process volume 105. The batch electrode device 536 is electrically coupled to a power source 138, such that each of the electrodes 506a-506f are electrically coupled to the power source 138. In some embodiments, the power source 138 includes multiple power sources.

The batch carrier 501 is disposed along the sidewall track 510 and includes a plurality of single substrate carriers or single carriers 502a-502f. The plurality of single carriers 502a-502f are coupled together by one or more support beams 504. The plurality of single carriers 502a-502f are parallel to one another and spaced apart along the one or more support beams 504. The plurality of single carriers 502a-502f are centered about a batch carrier axis C. The batch carrier axis C is parallel to the direction in which the one or more support beams 504 run. The batch carrier 501 is coupled to the chamber body by an actuator 505. The actuator 505 is coupled to the sidewall track 510. The actuator 505 is configured to attach the batch carrier 501 to the sidewall track 510 and rotate the batch carrier 501 about the rotation axis E. The plurality of single carriers 502a-502f are grounded. In some embodiments, the batch carrier 501 is a cassette having slots for retaining individual substrates.

The sidewall track 510 is a vertical track attached to and disposed along a sidewall of the one or more sidewalls 104. The sidewall track 510 is a linear track and may be coupled to the one or more sidewalls 104 using fasteners. The sidewall track 510 may extend above the level at which the chamber body 102 is filled with the intermediate medium 139. In some embodiments, the sidewall track 510 extends out of the chamber volume 105 and above the top surface 140 of the one or more sidewalls 104. The sidewall track 510 extends out of the chamber volume 105 to allow for complete rotation of the batch carrier 501 to a horizontal position without the batch carrier 501 impacting the batch electrode device 536.

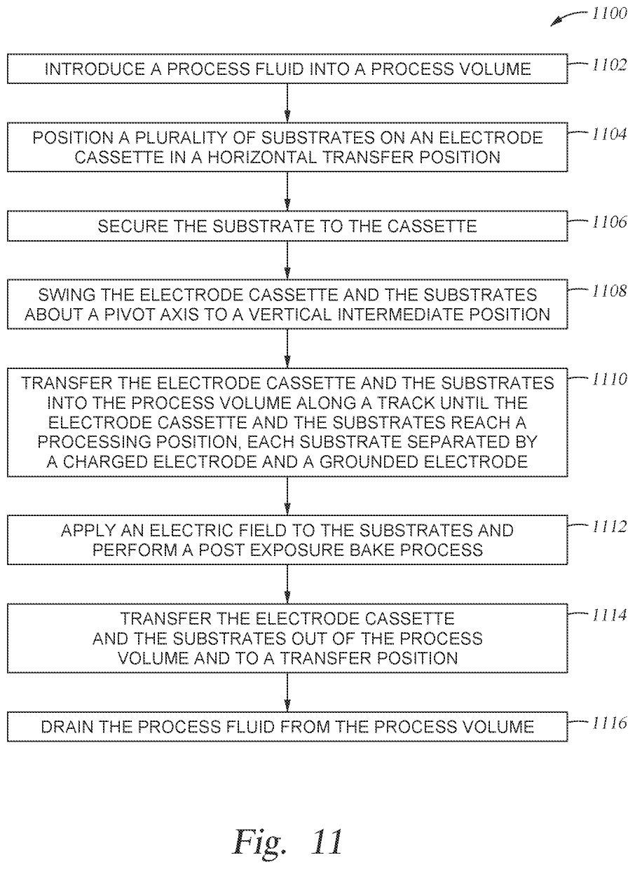

FIGS. 5A-5D illustrate process operations within the method 1100 of FIG. 11. The method 1100 of FIG. 11 further includes a first operation 1102, a second operation 1104, a third operation 1106, a fourth operation 1108, a fifth operation 1110, a sixth operation 1112, a seventh operation 1014, and an eighth operation 1016. The first operation 1102, the second operation 1104, and the third operation 1106 are completed while the batch carrier 501 is in a transfer position as shown in FIG. 5A. The first operation 1102 includes introducing a process fluid, such as the intermediate medium 139, into the process volume 105. The first operation 1102 is similar to the first operation 802 of the method 800 of FIG. 8.

The second operation 1104 includes positioning a plurality of substrates 150 onto the batch carrier 501. The plurality of substrates 150 are placed on the batch carrier 501 by one or more robots (not shown), while the batch carrier 501 is in a horizontal transfer position. The horizontal transfer position is a position in which the surface of each of the substrates 150 positioned on the single carriers 502a-502f is parallel to the horizontal plane and perpendicular to the main surface of each of the electrodes 506a-506f.

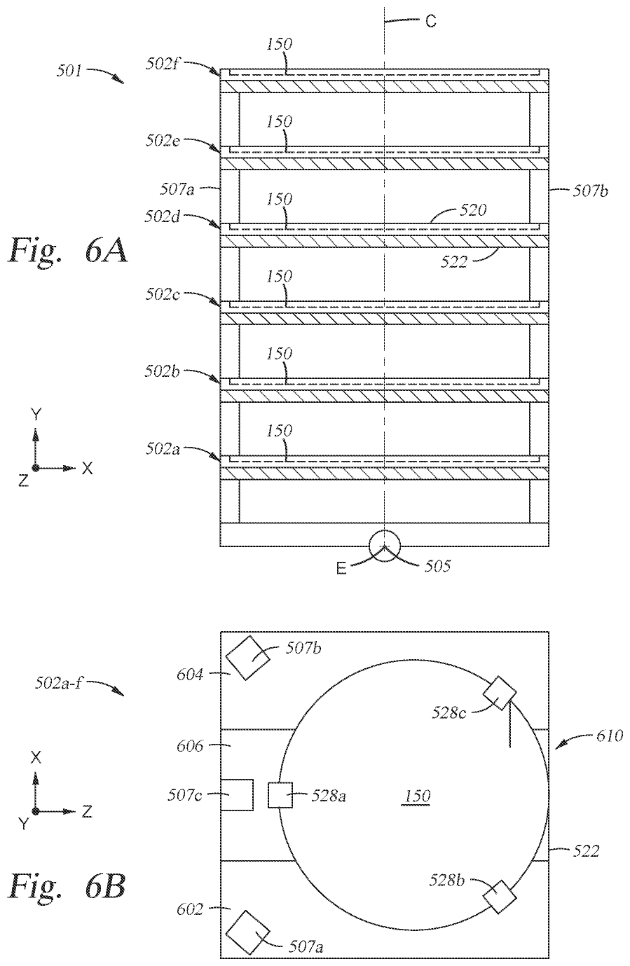

After the substrates 150 are placed on each of the single carriers 502a-502f of the batch carrier 501, the substrates 150 are secured to each of the single carriers 502a-502f during a third operation 1106. Each of the substrates 150 may be secured to the single carriers 502a-502f using one or more clamps 528a-528c (FIG. 6B). The one or more clamps 528a-528c may be either mechanical, pneumatic, or hydraulic clamps. The securing of the substrates 150 to the single carriers 502a-502f enables to the batch carrier 501 be rotated about the rotation axis E without the substrates 150 moving or falling out of the single carriers 502a-502f.

After the substrates 150 are secured to the batch carrier 501, the batch carrier 501 and the substrates 150 are swung about the rotation axis E during a fourth operation 1108. The swinging of the batch carrier 501 about the rotation axis E, swings the batch carrier 501 and the substrates 150 by an angle 84 to a vertical intermediate position. FIG. 5B illustrates the orientation of the batch carrier 501 after the fourth operation 1108. The angle 84 over which the batch carrier 501 swings is about 80 degrees to about 90 degrees, such as about 85 degrees to about 90 degrees, such as about 90 degrees. After the fourth operation 1108 is performed, the top surfaces of the substrates 150 are parallel to the bottom surfaces of each of the electrodes 506a-506f and the batch carrier axis C is parallel to the batch electrode axis D.

After the fourth operation 1108, the single carriers 502a-502f and the substrates 150 are partially submerged within the intermediate medium 139 or not submerged at all depending upon the depth of the intermediate medium 139 and the location of the electrodes 506a-506f.

After the fourth operation 1108, the batch carrier 501 and the substrates 150 are transferred into the process volume 105 along the sidewall track 510 during a fifth operation 1110. The batch carrier 501 and the substrates 150 are transferred to a processing position as shown in FIG. 5C, wherein one or more of the single carriers 502a-502f contact the supports 503 disposed at the bottom surface 124 of the chamber body 102. The supports are electrically insulated and assist in aligning the batch carrier 501 with the batch electrode device 536. While in the processing position, each of the substrates 150 are separated by both one of the electrodes 506a-506f and one of the single carriers 502a-502f. The electrodes 506a-506f serve as charged electrodes and the single carriers 502a-502f serve as grounded electrodes to create an electric field between the substrates 150 and the electrodes 506a-506f. The batch carrier axis C and the batch electrode axis D are aligned while in the processing position, such that each of the single carriers 502a-502f are centered with one of the electrodes 506a-506f.

The top surface of one of the substrates 150 is separated from the bottom surface of one of the electrodes 506a-506f by a distance D₁. The distance D₁ is less than about 7 mm, such as less than about 5 mm, such as less than about 3 mm, such as less than about 1 mm, such as less than about 0.5 mm. In the embodiment described herein, it is possible to reduce the distance D₁ as there are limited mechanical barriers between the device side of the substrate 150 and the electrodes 506a-506f.

After the fifth operation 1110, an electric field is applied to each of the substrates 150 within the batch carrier 501 during a sixth operation 1112. The sixth operation 1112 is similar to the eighth operation 816 of the method 800 of FIG. 8. After the post exposure bake process of the sixth operation 1112 is performed, batch carrier 501 is transferred out of the process volume 105 during a seventh operation 1114. During the seventh operation 1114, the batch carrier 501 is removed from the intermediate medium 139 in a method similar to, but reversed from, the method utilized to place the batch carrier 501 within the process volume 105.

During a eighth operation 1116, the process fluid, such as the intermediate medium 139, is drained from the process volume 105 through one of the first fluid source 120, the second fluid source 125, or the overflow valve 129. The draining of the process fluid from the process volume 105 during the eighth operation 1116 is similar to the tenth operation 820 of the method 800 of FIG. 8.

FIG. 6A is a schematic cross-sectional side view of the batch carrier 501 utilized with the immersion field guided post exposure bake chamber of FIGS. 5A-5C according to an embodiment described herein. The batch carrier 501 includes a plurality of single carriers 502a-502f. In the embodiment of FIG. 6A, there are six single carriers 502a-502f, but it is contemplated that any number of single carriers 502a-502f could be utilized. In some embodiments, the batch carrier 501 includes two or more single substrate carriers, such as three or more single substrate carriers. Each of the single substrate carriers, such as the single carriers 502a-502f are connected to one or more support beams 507a, 507b. In the embodiment of FIG. 6A, there is a first support beam 507a and a second support beam 507b. Each of the support beams 507a, 507b connect the single carriers 501a-502f together to form the batch carrier 501. The batch carrier 501 further includes the actuator 505 disposed on one end thereof for rotating of the batch carrier 501.

Each of the single carriers 502a-502f include a holding portion 520 and an insulated portion 522. The holding portion 520 is configured to hold the substrate 150. The insulated portion 522 is formed from an insulating material for electrically insulating the substrate 150 from the magnetic field of any electrodes, such as the electrodes 506a-506f disposed below the insulated portion 522. The holding portion 520 is disposed above the insulated portion 522, such that each substrate 150 has an insulated portion 522 disposed therebetween while disposed on the batch carrier 501.

FIG. 6B is a schematic cross-sectional plan view of a single substrate carrier 502a-502f of the batch carrier 501 of FIG. 6A according to an embodiment described herein. The single substrate carrier 502a-502f is shown and includes a first portion 602, a second portion 604, and a span portion 606. The first portion 602 and the second portion 604 are connected by the span portion 606 at one side of the single carrier 502a-502f. The substrate 150 is placed into a depression formed within both the first portion 602 and the second portion 604 in a similar manner to the depression 316 of FIG. 3A.

An opening 610 is disposed between the first portion 602 and the second portion 604 and opposite the span portion 606. The opening 610 is disposed to allow for a robot (not shown) to place and remove the substrate 150 from the single carrier 502a-502f, such that a blade of the robot is temporarily inserted between the first portion 602 and the second portion 604. Once the substrate 150 has been placed on the single carrier 502a-502f by the robot, one or more mechanical clamps 528a, 528b, 528c are actuated to a clamping position to secure the substrate 150. The one or more mechanical clamps includes a first clamp 528a, a second clamp 528b, and a third clamp 528c. The first clamp 528a is attached to the span portion 606, the second clamp 528b is attached to the second portion 604, and the third clamp 528c is attached to the first portion 602. Each of the first clamp 528a, the second clamp 528b, and the third clamp 528c are evenly distributed about the depression, such that each of the clamps 528a, 528b, 528c is disposed at an angle of about 180 degrees from one another. In some embodiments, there may be more or less clamps to secure the substrate 150. In some embodiments a hydraulic or a pneumatic clamp may be used.

The support beams 507a, 507b are disposed through the single carrier 502a-502f. The first support beam 507a is connected to the first portion 602 and the second support beam 507b is connected to the second portion 604. Each of the support beams 507a, 507b are disposed around an outer edge of the single carrier 502a-502f and are configured to allow the substrate 150 to be placed onto the single carrier 502a-502f through the opening 610. Underneath the single carrier 502a-502f is the insulated portion 522. The insulated portion 522 is disposed underneath the whole of the single carrier 502a-502f and the substrate 150.

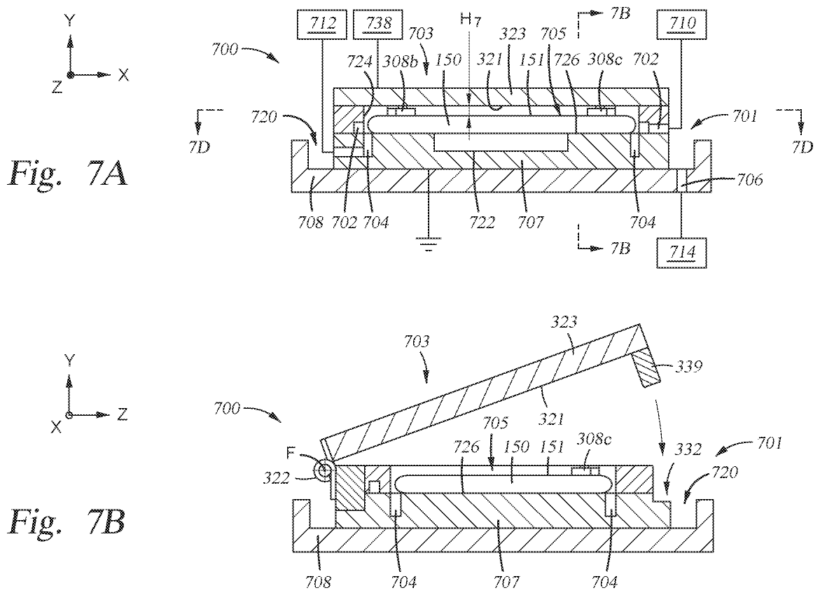

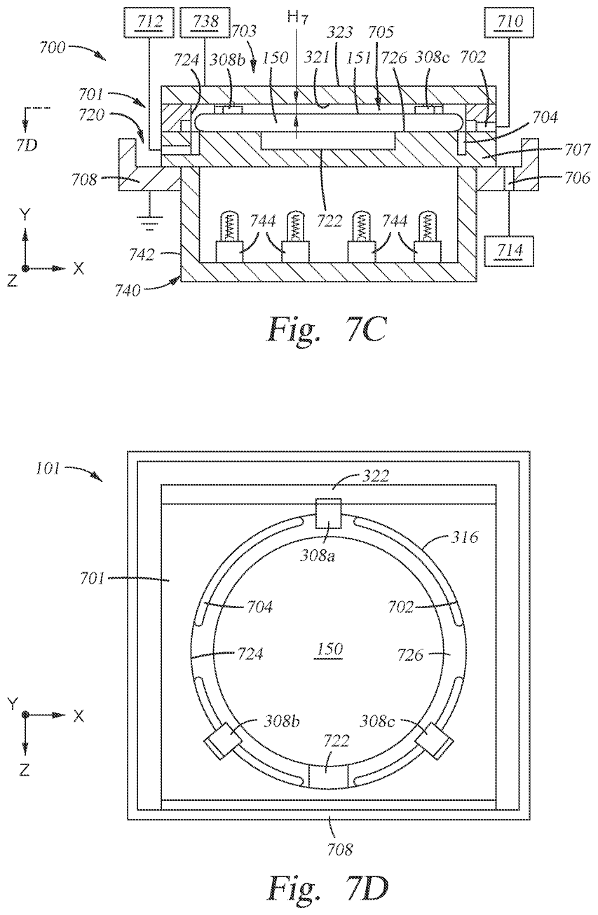

FIG. 7A is a schematic cross-sectional view of an immersion field guided post exposure bake chamber 700 according to yet another embodiment. The immersion field guided post exposure bake chamber 700 of FIG. 7A includes similar elements to the substrate carrier 201 of FIGS. 2A-2C and 3D-3F. The immersion field guided post exposure bake chamber 700 includes a base portion 701 and an electrode assembly 703. The electrode assembly 703 is coupled to the base portion 701 and configured to move between an opened and a closed position to allow the entry and exit of a substrate, such as the substrate 150. The substrate 150 is placed within the base portion 701 before the electrode assembly 703 moves to a closed position. The movement of the electrode assembly 703 may be a rotation, a swinging motion, or a linear movement. The electrode assembly 703 and the base portion 701 form a process volume 705. The process volume 705 is filled with a process fluid before an electric field is applied to the substrate 150 by the electrode assembly 703.

The base portion 701 of the immersion field guided post exposure bake chamber 700 includes a body 707 and a weir 708. The body 707 forms the bottom surface 726 and the sidewalls 724 of the base portion 701. The sidewalls 724 extend upwards from the bottom surface 726 and towards the electrode assembly 703. The bottom surface 726 is configured to support the substrate 150 and includes a cavity 722 disposed below the substrate 150. The cavity 722 is configured to allow a robot blade (not shown) to be disposed therein, such that the substrate 150 may be placed on the bottom surface 726 by a robot blade and the robot blade could then be removed from beneath the substrate 150 without contacting any of the components of the base portion 701. The sidewalls 724 surround at least a portion of the substrate 150.

The base portion 701 further includes one or more fluid inlets 702 and one or more fluid outlets 704. The one or more fluid inlets 702 may be a plurality of fluid inlets 702 surrounding the substrate 150 and disposed along the inner surface of the sidewalls 724. The one or more fluid outlets 704 are a plurality of outlets 704 surrounding the substrate 150 and disposed through the bottom surface 726 of the body 707. The one or more fluid inlets 702 are in fluid communication with a fluid source 710. The fluid source 710 is similar to the first fluid source 123. The fluid source 710 supplies processing fluid to the process volume 705. The one or more fluid outlets 704 are in fluid communication with an evacuation pump 712. The evacuation pump 712 is configured to remove the process fluid from the process volume 705 after the substrate 150 has been processed using an electric field. The one or more fluid outlets 704 are disposed through the bottom surface 726 of the base portion 701 to allow all fluid to be removed from the process volume 705 regardless of the fill level. In some embodiments, the one or more fluid inlets 702 may also be formed through the bottom surface 726. Each of the fluid inlets 702 and the fluid outlets 704 are parts of an annular channel disposed within the base portion 701. Each of the fluid source 710 and the evacuation pump 712 are in fluid contact with annular channels disposed through the base portion 701, wherein the annular channels are in fluid communication with the process volume 705 through the fluid inlets 702 and the fluid outlets 704 respectively.

The substrate 150 is clamped to the bottom surface 726 of the base portion 701 by one or more mechanical clamps 308a, 308b, 308c. The one or more mechanical clamps 308a, 308b, 308c are described in greater detail with respect to FIGS. 3A-3F. The one or more mechanical clamps 308a, 308b, 308c secure the substrate 150 to the base portion 701 and prevent movement of the substrate 150 as the fluid fills or is drained from the process volume 705. The one or more mechanical clamps 308a, 308b, 308c additionally aid in preventing fluid from filling the cavity 722 or from gas from leaking out from underneath the substrate 150 during processing.

The electrode assembly 703 is disposed on top of the base portion 701 and forms a lid. The electrode assembly 703 includes a perforated electrode 323. The perforated electrode 323 is described in greater detail with respect to FIGS. 3D-3F. The bottom surface 321 of the perforated electrode 323 faces the substrate 150. The distance between the bottom surface 321 of the perforated electrode 323 and the top surface 151 of the substrate 150 is a seventh height H₇. The seventh height H₇ is less than about 7 mm, such as less than about 5 mm, such as less than about 3 mm, such as less than about 1 mm, such as less than about 0.5 mm. In the embodiment described herein, it is possible to reduce the seventh height H₇ as there are limited mechanical barriers between the device side of the substrate 150 and the perforated electrode 323. The electrode assembly 703 is electrically coupled to a power source 738. The power source 738 is configured to apply power to the perforated electrode 323. In some embodiments, an electrical potential of up to 5000 V is applied to the perforated electrode 323 by the power source 738, such as less than 4000 V, such as less than 3000 V. The base portion 701 is grounded and grounds the substrate to form a second electrode opposite the perforated electrode 323.

The weir 708 is disposed outside of the process volume 705. The weir 708 is coupled to the base portion 701 and collects excess fluid which escapes through the perforated electrode 323. The weir 708 includes a basin 720 disposed between the weir 708 and the base portion 701. In some embodiments, process fluid from the process volume 705 spills out of the process volume 705 through the perforated electrode 323. The use of excess process fluid may be beneficial and utilized to reduce the amount of bubbles within the process volume 705 during application of the electric field 914. An outlet 706 is formed through the weir 708 and fluidly couples a second evacuation pump 714 to the basin 720 to allow for fluid removal from the basin 720. The weir 708 and the basin 720 may surround the base portion 701.

FIG. 7B is another schematic cross-sectional side view of the immersion field guided post exposure bake chamber 700 of FIG. 7A taken through plane 7B-7B. As shown in FIG. 7B, the electrode assembly 703 may swing to an open position. The perforated electrode 323 swings to an open position about the axis F because of the actuator 322. Similarly to the actuator 322 of FIG. 3D-3F, the actuator 322 is coupled to one end of the perforated electrode 323 as well as the base portion 701. The protrusion 339 is formed in an outer groove 332 in a similar fashion to the embodiment of the substrate carrier 201 described in FIG. 3D-3F. The protrusion 339 forming a wall along the side of the substrate furthest from the actuator 322 is beneficial in that it may assist in retaining processing fluid within the process volume 705.

FIG. 7C is a schematic cross-sectional view of an immersion field guided post exposure bake chamber 700 according to yet another embodiment described herein. The immersion field guided post exposure bake chamber 700 is similar to that described with respect to FIGS. 7A and 7B, but additionally includes a heating assembly 740 disposed below the base portion 701. The heating assembly 740 is coupled to the bottom of the bottom of the base portion 701 and the weir 708. The heating assembly 740 may beneficially allow for rapid and uniform heating of the substrate 150. As the distance between the substrate 150 and the heating assembly 740 is small, there is less thermal mass between the substrate 150 and the heating assembly 740 to cause non-uniformities or delays in heating/cooling. The heating assembly 740 of FIG. 7C includes a housing 742 and a plurality of lamps 744 disposed within the housing 742. The housing 742 is coupled to the base portion 701 and may be used to direct the energy from the lamps 744 towards the process volume 705. In some embodiments, the inner surface of the housing 742 may be a reflective surface to reduce the amount of energy absorbed by the housing. An opening may be formed through the weir 720 to enable the housing 742 to be coupled to the base portion 701.

FIG. 7D is a plan view of the immersion field guided post exposure bake chamber 700 of FIGS. 7A-7C according to embodiments described herein. As shown in FIG. 7D, each of the one or more fluid inlets 702 and the one or more fluid outlets 704 are disposed around the circumference of the substrate 150. In some embodiments, each of the one or more fluid inlets 702 and the one or more fluid outlets 704 are arc-shaped and curved around a portion of the circumference of the substrate 150. In some embodiments, each of the one or more fluid inlets 702 and the one or more fluid outlets 704 are formed around greater than about 20 degrees of the circumference of the substrate 150, such as greater than about 30 degrees, such as greater than about 45 degrees. In some embodiments, there are two or more fluid inlets 702 and fluid outlets 704, such as three or more fluid inlets 702 and fluid outlets 704, such as four or more fluid inlets 702 and fluid outlets 704. The cavity 722 may be disposed between two of the fluid inlets 702 or two of the fluid outlets 704 so as not to intersect either of the fluid inlets 702 or the fluid outlets 704. The perforated electrode 323 would be disposed over the base portion 701 shown in FIG. 7D.

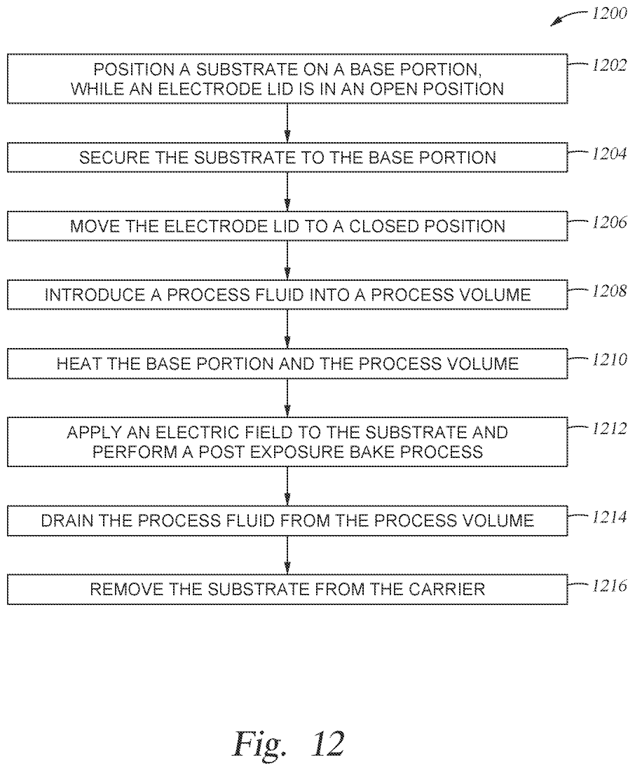

The apparatus of FIGS. 7A-7D enable the utilization of operations discussed with reference to the method 1200 of FIG. 12. The method 1200 begins at a first operation 1202 by positioning a substrate within the base portion 701.

The first operation 1202 includes positioning a substrate, such as the substrate 150, within the base portion 701, while the electrode assembly 703 is in an open position. The open position of the first operation 1202 is illustrated in FIG. 7B as the perforated electrode 323 is disposed at an angle to the substrate 150 and the substrate 150 is able to be placed or removed from the base portion 701.

Subsequent to the first operation 1202, a second operation 1204 is performed to secure the substrate 150 to the base portion 701. Securing the substrate 150 to the base portion 701 may include clamping the substrate 150 with the one or more mechanical clamps 308a, 308b, 308c and/or swinging the perforated electrode 323 to a closed position.

In some embodiments, swinging the perforated electrode 323 to a closed position is part of a third operation 1206 subsequent to the securing of the substrate 150, or in some embodiments, the second operation 1204 and the third operation 1206 are performed simultaneously.

Subsequent to the third operation 1206, a fourth operation 1208 of introducing a process fluid into the process volume 705 is performed. The process fluid enters the process volume 705 through the one or more fluid inlets 702 and fills the process volume 705. Some of the process fluid may spill out of the process volume 705 through the perforated electrode 323 and fall into the weir 708. Subsequent to or simultaneously with the introduction of the process fluid, a fifth operation 1210 is performed to heat the base portion 701 and the process volume 705. Heating the base portion 701 and the process volume 705 may be performed with one of the heating assembly 740 of FIG. 7C or another heating assembly, such as a resistive heating assembly. The substrate 150 is heated by the heating assembly 740. The temperature of the substrate 150 is controlled to improve processing results.

Subsequent to the heating during the fifth operation 1210, a sixth operation 1212 is performed by applying an electric field to the substrate 150 by the perforated electrode 323. Applying the electric field performs a post exposure bake process on the substrate and the photoresist disposed thereon. After the post exposure bake process of the sixth operation 1212, the process fluid is drained from the process volume 105 through the one or more fluid outlets 704 during a seventh operation 1214 and the substrate 150 is removed by an indexing robot (not shown) during an eighth operation 1216.

Embodiments described herein are beneficial in that substrates may be processed horizontally, while reducing bubbling effects on the post exposure bake process. Embodiments described herein also allow for the electrodes and substrate to be disposed closer together during processing, which reduces the impact of electric field non-uniformities.

While the foregoing is directed to embodiments of the present disclosure, other and further embodiments of the disclosure may be devised without departing from the basic scope thereof, and the scope thereof is determined by the claims that follow.

What is claimed is:

1. A substrate process apparatus, comprising:
a chamber body defining a process volume, the chamber body comprising:
a bottom surface;
one or more sidewalls; and
a fluid port disposed through the bottom surface of the chamber body;
a substrate carrier;
an electrode disposed above the bottom surface comprising a major surface;
a track disposed within the chamber body and configured to guide the substrate carrier to a processing position, a device side of each of one or more substrates parallel to a major surface of the electrode while in the processing position;
an actuator operable to position the substrate carrier in a position parallel to at least a portion of the carrier track.

2. The substrate processing apparatus of claim 1, wherein track comprises:
a first track segment disposed at a first angle to the bottom surface of the chamber body;
a transition track segment coupled to the first track segment; and
a second track segment coupled to the transition track segment and parallel to the major surface of the electrode.

3. The substrate processing apparatus of claim 2, wherein a loading device is coupled to the actuator and configured to swing the substrate carrier from a loading position to an angled position parallel to the first track segment.

4. The substrate processing apparatus of claim 3, wherein the angled position is about 60 degrees to about 90 degrees relative to a horizontal plane.

5. The substrate processing apparatus of claim 1, wherein the distance between the electrode and the substrate carrier while the substrate carrier is in the processing position is less than about 7 mm.

6. The substrate processing apparatus of claim 1, wherein the track is grounded.

7. The substrate processing apparatus of claim 1, wherein the substrate carrier includes one or more track connectors coupling the substrate carrier to the track.

8. The substrate processing apparatus of claim 1, wherein the substrate carrier is a batch carrier with a plurality of single carriers and the electrode is a batch electrode, wherein the batch electrode comprises a plurality of electrode devices, each of the plurality of electrode devices disposed parallel with one another.

9. The substrate processing apparatus of claim 8, wherein the track is coupled to the one or more sidewalls of the chamber body.

10. The substrate processing apparatus of claim 8, wherein each of the substrate carriers include an insulation layer disposed thereon.

11. A substrate process apparatus, comprising:
a chamber body defining a process volume, the chamber body comprising:
a bottom surface;
one or more sidewalls; and
a fluid port disposed through the bottom surface of the chamber body; and
a swing assembly comprising:
a substrate carrier comprising a substrate support surface;
an electrode disposed comprising a major surface parallel to the substrate support surface; and
an actuator coupled to the substrate carrier and the electrode and configured to swing the substrate carrier and the electrode about an axis.

12. The substrate processing apparatus of claim 11, wherein the chamber body includes one or more grounded connections disposed on the bottom surface.

13. The substrate processing apparatus of claim 11, wherein the substrate carrier is electrically isolated from the electrode.

14. The substrate processing apparatus of claim 11, wherein the electrode is electrically coupled to a power source.

15. The substrate processing apparatus of claim 11, wherein a fluid accumulation basin is disposed below outside of the one or more sidewalls of the chamber body.

16. A substrate processing method, comprising:
positioning one or more substrates on a substrate carrier while the substrate carrier is in a transfer position, the one or more substrates on the substrate carrier having a substantially horizontal orientation when the substrate carrier is in the transfer position;
flowing a processing fluid from a fluid port into a process volume of a chamber body;
orienting the substrate carrier in a fluid entry position, wherein the one or more substrates are disposed on the substrate carrier in the fluid entry position having a fluid entry orientation that is about 60 degrees to about 90 degrees from the substantially horizontal orientation;
submerging at least a portion of the one or more substrates disposed on the substrate carrier into the processing fluid while in the fluid entry orientation;
positioning the substrate carrier at a processing position, wherein the one or more substrates disposed on the substrate carrier are fully submerged within the processing fluid and a device side of the substrate is parallel to a major surface of a second electrode.

17. The substrate processing method of claim 16, wherein the major surface of the electrode is perpendicular to the bottom surface of the chamber body while in the processing position.

18. The substrate processing method of claim 16, wherein after submerging at least a portion of the substrate into the processing fluid, the substrate carrier is swung about an axis such that the device side of the substrate is parallel to the bottom surface of the chamber body.

19. The substrate processing method of claim 16, wherein the substrate carrier is transported along a track and rotated, such that the device side of the substrate is parallel to the bottom surface of the chamber body.

20. The substrate processing method of claim 16, wherein the processing fluid flows over a top surface of one or more sidewalls of the chamber body and into a fluid accumulation basin disposed outside of the chamber body.

21. A substrate process apparatus, comprising:
a base assembly defining a process volume, the base assembly comprising:
a bottom surface;
one or more sidewalls;
a fluid inlet disposed through the chamber body; and
a fluid outlet disposed through the chamber body; and
an electrode assembly, the electrode assembly comprising:
a perforated electrode; and
an actuator coupled to a side of the perforated electrode and the base assembly.

22. The substrate process apparatus of claim 21, wherein the perforated electrode is an electrode mesh.

23. The substrate process apparatus of claim 21, wherein the actuator is configured to swing the perforated electrode about an axis.

24. The substrate process apparatus of claim 21, wherein the base assembly further comprises a weir disposed outside of the one or more sidewalls.

25. The substrate process apparatus of claim 21, further comprising a heating assembly coupled to the base assembly.

26. The substrate process apparatus of claim 21, further comprising one or more clamps within the process volume.
